(19) United States
(12) Patent Application Publication
(10) Pub. No.: US 2025/0063724 A1
(43) Pub. Date: Feb. 20, 2025

(54) SEMICONDUCTOR DEVICE

(71) Applicant: SAMSUNG ELECTRONICS CO., LTD., SUWON-SI (KR)

(72) Inventors: GYUHWAN OH, Suwon-si (KR); JINWOO HAN, Suwon-si (KR); SEOKHAN PARK, Suwon-si (KR); SUNG-MIN PARK, Suwon-si (KR); BOWON YOO, Suwon-si (KR)

(21) Appl. No.: 18/614,839

(22) Filed: Mar. 25, 2024

(30) Foreign Application Priority Data
Aug. 14, 2023 (KR) 10-2023-0106397

(51) Int. Cl. H10B 12/00; H01L 23/522

(52) U.S. Cl. CPC H10B 12/482; H01L 23/5225; H10B 12/02; H10B 12/315; H10B 12/488; H10B 12/50

(57) ABSTRACT

A semiconductor device includes a substrate. Bit lines are disposed on the substrate and extend in a first direction. A shield pattern is disposed on the bit lines. A first word line is disposed on the bit lines. The first word line extends in a second direction crossing the first direction. A second word line extends on the bit lines in the second direction and is spaced apart from the first word line in the first direction. A first active pattern and a second active pattern are disposed on the bit lines and are positioned between the first word line and the second word line. The shield pattern includes an opening pattern disposed between adjacent bit lines of the bit lines.

### CROSS-REFERENCE TO RELATED APPLICATION

This application claims priority under 35 U.S.C. § 119 to Korean Patent Application No. 10-2023-0106397, filed on Aug. 14, 2023 in the Korean Intellectual Property Office, the disclosure of which is incorporated by reference in its entirety herein.

### 1. Technical Field

The present disclosure relates to a semiconductor device.

### 2. Discussion of Related Art

In view of the increasing consumer demand for electronic devices having a high performance and low price, the integration level of semiconductor memory devices should be increased. For example, semiconductor memory devices should have an increased integration level because the integration level is an important factor in determining the price of the product.

In the case of two-dimensional or plan semiconductor memory devices, the integration level is mainly determined by the area occupied by the unit memory cell. Therefore, the integration level is greatly affected by a level of a fine pattern formation technology. However, very expensive equipment is required to refine the pattern. Thus, the integration level of the two-dimensional semiconductor memory devices is limited.

Accordingly, research is being conducted concerning semiconductor memory devices including a vertical channel transistor of which the channel extends in the vertical direction.

### SUMMARY

Embodiments of the present disclosure are intended to provide semiconductor devices with increased reliability and productivity.

According to an embodiment of the present disclosure, a semiconductor device includes a substrate. Bit lines are disposed on the substrate and extend in a first direction. A shield pattern is disposed on the bit lines. A first word line is disposed on the bit lines. The first word line extends in a second direction crossing the first direction. A second word line extends on the bit lines in the second direction and is spaced apart from the first word line in the first direction. A first active pattern and a second active pattern are disposed on the bit lines and are positioned between the first word line and the second word line. The shield pattern includes an opening pattern disposed between adjacent bit lines of the bit lines.

According to an embodiment of the present disclosure, a semiconductor device includes a substrate including a cell array region and a connection region. Bit lines are disposed on the substrate and extend in a first direction. A shield pattern is disposed on the bit lines. A first word line is disposed on the bit lines. The first word line extends in a second direction crossing the first direction. A second word line extends on the bit lines in the second direction and is spaced apart from the first word line in the first direction. A first active pattern and a second active pattern are disposed on the bit lines and are positioned between the first word line and the second word line. A back gate electrode is respectively disposed between the first and second active patterns adjacent to each other. The back gate electrode extends across the bit lines in the second direction. The shield pattern includes first portions disposed between the bit lines. A second portion is connected to the first portions and is disposed on a lower surface of the bit lines. A plurality of opening patterns is disposed between adjacent bit lines of the bit lines. Each of the plurality of opening patterns disposed between the bit lines has a substantially same total sum of an area.

According to an embodiment of the present disclosure, a semiconductor device includes a substrate including a cell array region and a connection region. A peripheral circuit structure is disposed on the substrate. The peripheral circuit structure includes peripheral circuits and a peripheral circuit insulation layer covering the peripheral circuits. Bit lines are disposed on the peripheral circuit structure and extend in a first direction. A shield pattern is disposed between the substrate and the bit lines and includes a plurality of opening patterns. A first word line is disposed on the bit lines. The first word line extends in a second direction crossing the first direction. A second word line is disposed on the bit lines. The second word line extends in the second direction and is spaced apart from the first word line in the first direction. A first active pattern and a second active pattern are disposed on the bit lines and are positioned between the first word line and the second word line. A back gate electrode is disposed respectively between the first and second active patterns. The back gate electrode extends across the bit lines in the second direction. A shield insulation pattern fills the plurality of opening patterns. The shield pattern includes first portions disposed between the bit lines. A second portion connected to the first portions and disposed on a lower surface of the bit lines. Each of the plurality of opening patterns disposed between adjacent bit lines of the bit lines has a substantially same total sum of an area.

According to embodiments, as the plurality of opening patterns included in the shield pattern is disposed between the bit lines adjacent to each other, a parasitic capacitance that occurs between the shield pattern and the bit line may be reduced, and simultaneously a coupling capacitance caused by a mutual interference between the adjacent bit lines may be reduced.

### BRIEF DESCRIPTION OF THE DRAWINGS

FIG. 1 is a top plan view of a semiconductor device according to an embodiment.

FIG. 2 is a top plan view showing a bit line and a shield pattern of FIG. 1 according to an embodiment.

FIG. 3 is a cross-sectional view taken along a line A-A′ of FIG. 1 according to an embodiment.

FIG. 4 is a partial enlarged view enlarging a region P1 of FIG. 3 according to an embodiment.

FIG. 5 is a cross-sectional view showing a cross-section taken along a line B-B′ and a line C-C′ of FIG. 1 and a cross-section of a word line connection region according to an embodiment.

FIG. 6 is a partial enlarged view enlarging a region P2 of FIG. 5 according to an embodiment.

FIG. 7 is a partial enlarged view enlarging a region P3 of FIG. 5 according to an embodiment.

FIG. 8 is a cross-sectional view taken along a line A-A′ of FIG. 1 according to an embodiment.

FIG. 9 is a cross-sectional view showing taken along a line B-B′ and a line C-C′ of FIG. 1 and a cross-section of a word line connection region according to some embodiments.

FIG. 10, FIG. 13, FIG. 17, FIG. 20, FIG. 23, and FIG. 28 to FIG. 30 are plan views showing a bit line and a shield pattern of FIG. 1 according to some embodiments.

FIG. 11, FIG. 14, and FIG. 24 are cross-sectional views taken along a line A-A′ of FIG. 10, FIG. 13, and FIG. 23 according to some embodiments, respectively.

FIG. 12, FIG. 15, FIG. 18, FIG. 21, and FIG. 25 are cross-sectional views taken along a line B-B′ and a line C-C′ and cross-sections of a word line connection region of FIG. 10, FIG. 13, FIG. 17, FIG. 20, and FIG. 23, respectively, according to some embodiments.

FIG. 16 is a partial enlarged view enlarging a region P4 of FIG. 15 according to an embodiment.

FIG. 19 is a partial enlarged view enlarging a region P5 of FIG. 8 according to an embodiment.

FIG. 22 is a partial enlarged view enlarging a region P6 of FIG. 21 according to an embodiment.

FIG. 26 is a partial enlarged view enlarging a region P7 of FIG. 25 according to an embodiment.

FIG. 27 is a partial enlarged view enlarging a region P8 of FIG. 25 according to an embodiment.

FIG. 31, FIG. 32, FIG. 34, FIG. 35, and FIG. 38 to FIG. 49 are cross-sectional views to explain a manufacturing method of a semiconductor device according to some embodiments.

FIG. 33, FIG. 36A, and FIG. 36B are perspective views to explain a manufacturing method of a semiconductor device according to some embodiments.

FIG. 37 is a top plan view to explain a manufacturing method of a semiconductor device according to an embodiment.

FIG. 50 to FIG. 55 are perspective views to explain a manufacturing method of a semiconductor device according to some embodiments.

### DETAILED DESCRIPTION OF EMBODIMENTS

The present disclosure will be described more fully hereinafter with reference to the accompanying drawings, in which embodiments of the present disclosure are shown. As those skilled in the art would realize, the described embodiments may be modified in various different ways, all without departing from the spirit or scope of the present disclosure.

To clarify the present disclosure, parts that are not connected with the description will be omitted, and the same elements or equivalents are referred to by the same reference numerals throughout the specification.

Further, since sizes and thicknesses of constituent members shown in the accompanying drawings may be arbitrarily given for better understanding and ease of description, the present disclosure is not necessarily limited to the illustrated sizes and thicknesses. For example, in the drawings, the thickness of layers, films, panels, regions, etc., may be exaggerated for clarity. In the drawings, for better understanding and ease of description, thicknesses of some layers and areas may be excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

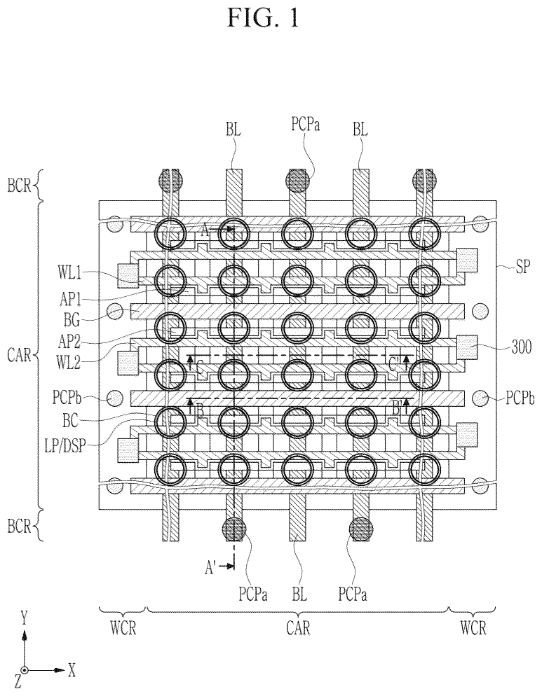

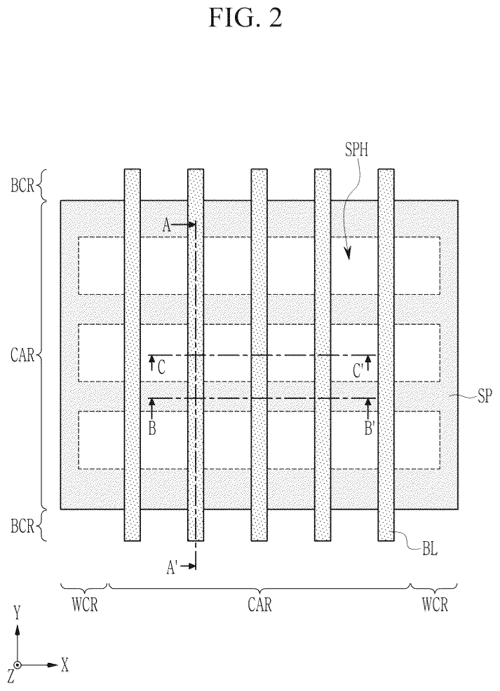

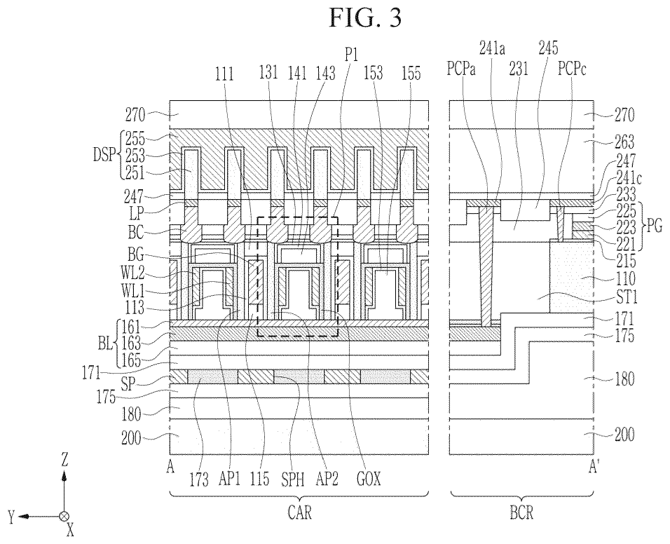

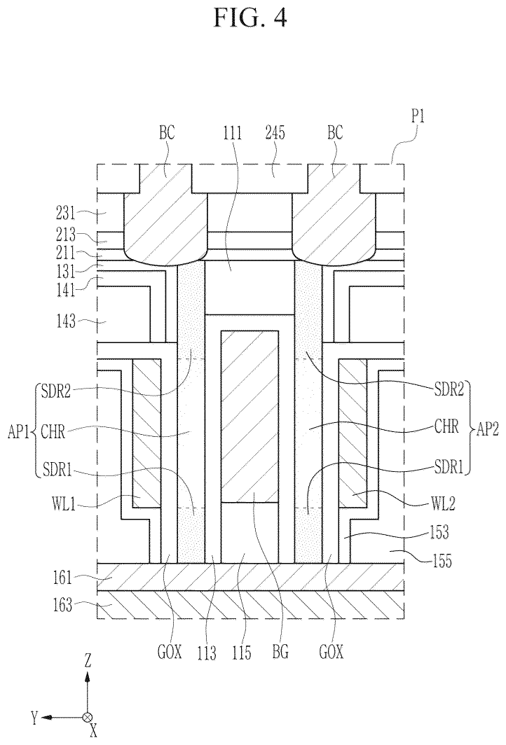

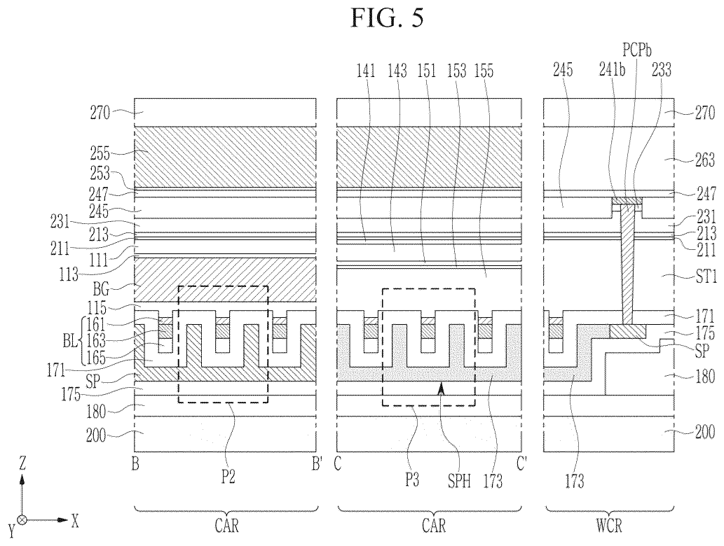

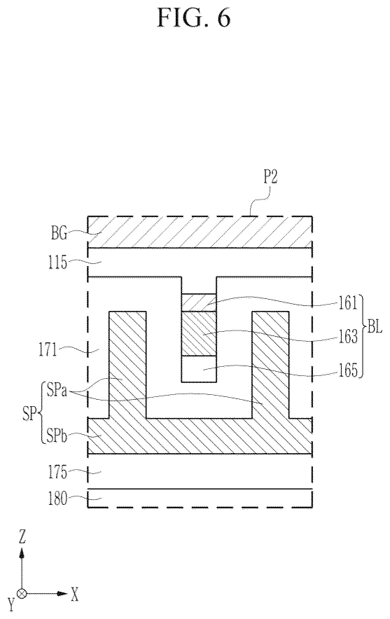

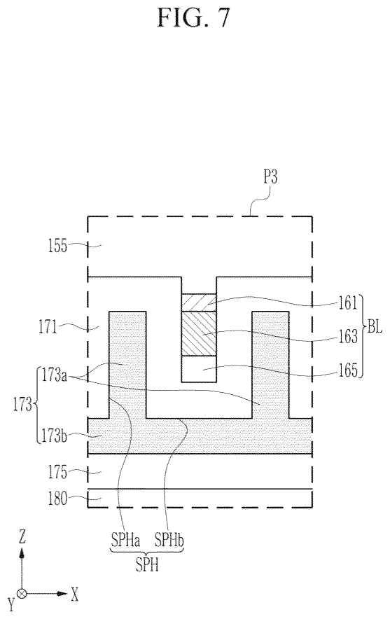

FIG. 1 is a top plan view of a semiconductor device according to embodiments. FIG. 2 is a top plan view showing a bit line and a shield pattern of FIG. 1. FIG. 3 is a cross-sectional view taken along a line A-A′ of FIG. 1. FIG. 4 is a partial enlarged view enlarging a region P1 of FIG. 3. FIG. 5 is a cross-sectional view showing a cross-section taken along a line B-B′ and a line C-C′ of FIG. 1 and a cross-section of a word line connection region. FIG. 6 is a partial enlarged view enlarging a region P2 of FIG. 5. FIG. 7 is a partial enlarged view enlarging a region P3 of FIG. 5.

A semiconductor device according to an embodiment of the present disclosure may include memory cells including a vertical channel transistor (VCT).

Referring to FIG. 1 to FIG. 7, in an embodiment a semiconductor device may include a substrate 200, bit lines BL, word lines WL1 and WL2, back gate electrodes BG, a shield pattern SP, first and second active patterns AP1 and AP2, and data storage patterns DSP.

In an embodiment, the substrate 200 may include a cell array region CAR, word line connection regions WCR, and a bit line connection regions BCR. The memory cells may be disposed in the cell array region CAR of the substrate 200.

In an embodiment, the cell array region CAR may be disposed between the word line connection regions WCR in a first direction X, and the cell array region CAR may be disposed between the bit line connection regions BCR in a second direction Y. In an embodiment, the second direction Y may be perpendicular to the first direction X. However, embodiments of the present disclosure are not necessarily limited thereto and the first and second directions X, Y may cross each other at various different angles. As shown in FIG. 1, the word line connection regions WCR may be disposed on one side and the other side in the first direction X of the cell array region CAR, and the bit line connection regions BCR may be disposed on one side and the other side in the second direction Y of the cell array region CAR. Hereinafter, the word line connection regions WCR may be referred to as first connection regions, and the bit line connection regions BCR may be referred to as second connection regions.

In an embodiment, the substrate 200 may be a silicon substrate, or may include other materials, such as silicon germanium, indium antimonide, lead tellurium compound, indium arsenic, indium phosphide, gallium arsenic or gallium antimonide. However, embodiments of the present disclosure are not necessarily limited thereto.

The bit lines BL may be disposed on the substrate 200 to be spaced apart from each other in the first direction X. The bit lines BL may extend parallel to each other in the second direction Y intersecting the first direction X. The bit lines BL may extend in the second direction Y from the cell array region CAR to the second connection regions BCR. Accordingly, a portion of the bit lines BL may be disposed in the second connection regions BCR, and the end of the bit lines BL may be disposed in the second connection region BCR.

In an embodiment, each of the bit lines BL may include a polysilicon layer 161, a metal layer 163, and a bit line hard mask layer 165 that are sequentially stacked.

In an embodiment, the polysilicon layer 161 may be an impurity-doped polysilicon, and the metal layer 163 may include a conductive metal nitride (e.g., titanium nitride, tantalum nitride, etc.) and a metal (e.g., tungsten, titanium, tantalum, etc.).

In an embodiment, the metal layer 163 may include a metal silicide such as titanium silicide, cobalt silicide, or nickel silicide.

In an embodiment, the bit line hard mask layer 165 may include an insulating material such as silicon nitride or silicon acid nitride.

In some embodiments, the bit lines BL may include two-dimensional and three-dimensional materials, such as graphene of a carbon-based two-dimensional material, carbon nanotube of a three-dimensional material, or combinations thereof.

FIG. 3 shows that the polysilicon layer 161 of the bit line BL is not disposed in the second connection region BCR. However, embodiments of the present disclosure are not necessarily limited thereto.

The shield pattern SP may be disposed on the bit lines BL and arranged between the substrate 200 and the bit lines BL (e.g., in a third direction Z that crosses the first and second directions X, Y and is a thickness direction of the substrate 200) in the cell array region CAR and the first connection regions WCR. Accordingly, the length along the first direction X of the shield pattern SP may be greater than the length along the first direction X of the later-described word lines WL1 and WL2, and the length along the second direction Y of the shield pattern SP may be less than the length along the second direction Y of the bit lines BL.

The shield pattern SP may be disposed on (e.g., disposed directly thereon) the spacer insulation layer 171 that defines gap regions between the adjacent bit lines BL, and the capping insulation layer 175 may be disposed on (e.g., disposed directly thereon) the shield pattern SP.

In an embodiment, the spacer insulation layer 171 has a substantially uniform thickness and may be disposed conformally on the bit lines BL. In an embodiment, the spacer insulation layer 171 may cover both side surfaces and the upper surfaces of the bit lines BL. The spacer insulation layer 171 may define the gap regions between the bit lines BL. The gap regions of the spacer insulation layer 171 may extend parallel to the bit lines BL in the second direction Y.

In an embodiment, the shield pattern SP may be composed of a conducting material, and the shield pattern SP may include a metallic material such as, for example, tungsten (W), titanium (Ti), nickel (Ni), or cobalt (Co). As another example, the shield pattern SP may include a conductive two-dimensional 2D material such as graphene.

The spacer insulation layer 171 may extend from the cell array region CAR to the first and second connection regions WCR and BCR. The spacer insulation layer 171 may cover the ends of bit lines BL in the second connection regions BCR.

In an embodiment, the spacer insulation layer 171 may include, for example, a silicon oxide layer, silicon nitride, a silicon nitride layer, and/or a low dielectric layer.

The shield pattern SP may be disposed on the spacer insulation layer 171 and may fill the gap regions of the spacer insulation layer 171.

As shown in FIG. 5 and FIG. 6, the shield pattern SP may include first portions SPa disposed between the adjacent bit lines BL, a second portion SPb commonly connecting the first portions Spa to each other, and an opening pattern SPH penetrating the shield pattern SP.

For example, the first portions SPa of the shield pattern SP may be disposed between the adjacent bit lines BL (e.g., in the first direction X). The first portions Spa of the shield pattern SP may fill the gap regions of the spacer insulation layer 171. Accordingly, the first portions SPa of the shield pattern SP and the side surfaces of the bit lines BL may be disposed to be spaced apart from each other via the spacer insulation layer 171 in the first direction.

FIG. 5 and FIG. 6 shows that the height along the third direction Z of the bit line BL is higher than the height along the third direction Z of the first portion SPa of the shield pattern SP. However, embodiments of the present disclosure are not necessarily limited thereto and the height along the third direction Z of the bit line BL and the height along the third direction Z of the first portion SPa of the shield pattern SP may be substantially equal to each other in some embodiments.

In an embodiment, the second portion SPb of the shield pattern SP may be connected to the first portions SPa and may be integrated with the first portion SPa. The second portion SPb of the shield pattern SP may disposed on the first portions SPa and connect the first portions SPa disposed between the adjacent bit lines BL. However, embodiments of the present disclosure are not necessarily limited thereto, and in some embodiments, the first portion SPa and the second portion SPb of the shield pattern SP may be formed of separate configurations.

The second portion SPb of the shield pattern SP may be disposed on the lower surface of the bit lines BL in the cell array region CAR and the first connection regions WCR. The second portion SPb of the shield pattern SP extends to one side and the other side in the first direction X from the cell array region CAR to the first connection regions WCR, and the second portion SPb of the shield pattern SP may extend from the first connection regions WCR to one side and the other side in the second direction Y. The end of the second portion SPb of the shield pattern SP may be disposed in the first connection regions WCR.

The second portion SPb of the shield pattern SP may overlap with the bit lines BL in the cell array region CAR (e.g., in the third direction Z) which is the vertical direction. The second portion SPb of the shield pattern SP and the lower surface of the bit lines BL may be disposed to be spaced apart from each other in the third direction Z via the spacer insulation layer 171 interposed therebetween.

The shield pattern SP according to an embodiment may include a plurality of opening patterns SPH penetrating the shield pattern SP. For example, the plurality of opening patterns SPH may be a portion from which a portion of the shield pattern SP is removed.

As shown in FIG. 2, the plurality of opening patterns SPH may be disposed in the cell array region CAR and the first connection regions WCR. For example, the plurality of opening pattern SPH may be extended to one side and the other side of the first direction X from the cell array region CAR to reach the first connection regions WCR. For example, the plurality of opening pattern SPH crosses the plurality of bit lines BL on a plane and extends in the first direction X, and the plurality of opening patterns SPH may overlap with the plurality of bit lines BL in the third direction Z.

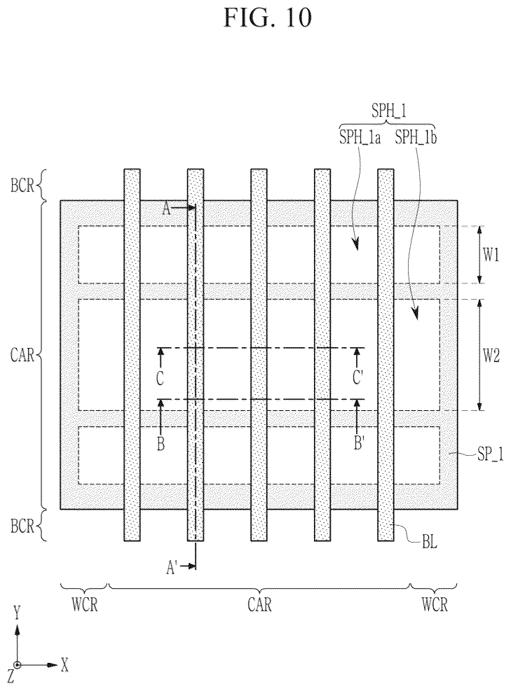

Additionally, the plurality of opening patterns SPH may be disposed to be spaced apart from each other in the second direction Y, which is the elongation direction of the bit lines BL. Each of the plurality of opening patterns SPH extends in the first direction X and may have a line shape on a plane. However, the number, shape, and arrangement of the opening pattern SPH included in the shield pattern SP are not necessarily limited thereto. The detailed description thereof may be described with reference to FIG. 10 to FIG. 30 later.

In an embodiment, each of plurality of opening patterns SPH may include a first opening region SPHa positioned between the adjacent bit lines BL (e.g., in the first direction X) and a second opening region SPHb connected to the first opening regions SPHa and positioned on the first opening regions SPHa.

The first opening region SPHa may correspond to a region where the first portion SPa of the shield pattern SP is patterned and a portion of the first portion SPa is removed, and the second opening region SPHb may correspond to a region in which the second portion SPb of the shield pattern SP is patterned and a portion of the second portion SPb is removed.

Each of the first opening regions SPHa of the opening pattern SPH may be disposed in the gap region of the spacer insulation layer 171. Accordingly, the first opening regions SPHa may be disposed between the adjacent bit lines BL in the cell array region CAR and may extend in the third direction Z on a cross-section. The side surface of the bit lines BL and the first opening region SPHa may be disposed to be spaced apart in the first direction vie the spacer insulation layer 171 interposed therebetween.

Additionally, the first opening region SPHa may be disposed on the side surface of the bit line BL in the first connection regions WCR.

In an embodiment, the total sum of the areas of the first opening regions SPHa disposed in each region between the adjacent bit lines BL may be substantially equivalent. For example, regardless of the number, shape, size, and arrangement of the first opening region SPHa disposed in each region between the adjacent bit lines BL, the total sum of the areas of the first opening regions SPHa disposed in each region between the adjacent bit lines BL may be substantially equivalent between the adjacent bit lines BL, respectively.

Here, the area may mean the planar area of the first opening region SPHa disposed between the adjacent bit lines BL, or the total sum of the areas of each of the inner surfaces constituting the first opening region SPHa in the cross-section.

Accordingly, the total sum of the areas of the first portions SPa of the shield pattern SP disposed between the adjacent bit lines BL may be substantially equivalent (e.g., substantially equal to each other). For example, the ratio occupied by the first portions SPa of the shield pattern SP in each region between the adjacent bit lines BL or the density of the first portions SPa of the shield pattern SP disposed in each region between the adjacent bit lines BL may be substantially equivalent.

For example, the first portions Spa of the shield pattern SP correspond to a portion of the shield pattern SP remaining between the bit lines BL adjacent to each other after forming the first opening region SPHa by patterning a portion of the shield pattern SP disposed between the bit lines BL adjacent to each other to be removed.

Therefore, if the total sum of the areas of the first opening regions SPHa disposed between the adjacent bit lines BL is substantially equivalent (e.g., substantially equal to each other), the total sum of the areas of the first portions SPa of the shield pattern SP disposed between the adjacent bit lines BL may also be substantially equivalent (e.g., substantially equal to each other). However, embodiments of the present disclosure are not necessarily limited thereto. For example, in some embodiments, considering the interval between the bit lines BL, the arrangement of the bit lines BL, and the arrangement relationship between the bit lines BL and other components, the shield pattern SP may be patterned so as to differentiate that the total area of the first opening regions SPHa disposed between the adjacent bit lines BL.

The second opening region SPHb may be disposed on the lower surface of the bit lines BL in the cell array region CAR and the first connection regions WCR and is connected to (e.g., directly connected thereto) the first opening regions SPHa. For example, the second opening region SPHb may be connected to the plurality of first opening regions SPHa.

The second opening region SPHb may overlap with bit lines BL in the cell array region CAR in the third direction Z which is the vertical direction. The second opening region SPHb and the lower surface of the bit lines BL may be disposed to be spaced apart from each other in the third direction Z via the spacer insulation layer 171 interposed therebetween.

In an embodiment, a shield insulation pattern 173 may be disposed within the opening pattern SPH of the shield pattern SP. For example, the shield insulation pattern 173 may fill (e.g., completely fill) the plurality of opening patterns SPH of the shield pattern SP.

As shown in FIG. 5 and FIG. 7, the shield insulation pattern 173 may include first portions 173a filling the first opening regions SPHa and second portions 173b filling the second opening region SPHb in each of the opening patterns SPH.

Each of the first portion 173a and the second portion 173b of the shield insulation patterns 173 may have substantially the same shape and arrangement as the first portion SPa and the second portion SPb of the shield pattern SP described above.

For example, the first portions 173a of the shield insulation pattern 173 are disposed between the adjacent bit lines BL (e.g., in the first direction X) and may extend in the third direction Z on a cross-section. Accordingly, the first portion 173a of the shield insulation pattern 173 and the side surface of the bit lines BL may be disposed to be spaced apart in the first direction X via the spacer insulation layer 171 interposed therebetween.

In an embodiment, the height of the first portion 173a of the shield insulation pattern 173 in the third direction Z may be lower than the height of the bit line BL in the third direction Z. For example, the end (e.g., an uppermost surface) of the first portion SPa of the shield pattern SP may be disposed at a lower level than the end (e.g., an uppermost surface) of the bit line BL. However, embodiments of the present disclosure are not necessarily limited thereto. For example, in an embodiment in which the height in the third direction Z of the first opening region SPHa of the opening pattern SPH is higher or substantially equivalent than the height in the third direction Z of the bit line BL, the height in the third direction Z of the first portion 173a of the shield insulation pattern 173 that fills the first opening region SPHa may be higher or substantially equivalent to the height along the third direction Z of the bit lines BL.

As shown in FIG. 2, between the adjacent bit lines BL, the first portion SPa of the shield pattern SP and the first opening region SPHa of the opening pattern SPH may be alternately disposed in the second direction Y. Accordingly, the first portion 173a of the shield insulation pattern 173 filled in the first opening region SPHa and the first portion SPa of the shield pattern SP may be alternately disposed in the second direction Y between the adjacent bit lines BL.

As described above, in an embodiment, as the total sum of the areas of the first opening regions SPHa disposed between the adjacent bit lines BL is substantially equivalent, the total sum of the areas of the first portions 173a of the shield insulation pattern 173 disposed between the adjacent bit lines BL may be substantially equivalent. However, embodiments of the present disclosure are not necessarily limited thereto. For example, in an embodiment in which the shield insulation pattern 173 fills only part of the first opening region SPHa, the total sum of the area of the first opening regions SPHa and the total sum of the area of the first portion 173a of the shield insulation pattern 173 may be different from each other.

The second portion 173b of the shield insulation pattern 173 may be connected to the first portion 173a of the shield insulation pattern 173 and disposed on the first portion 173a. The second portion 173b of the shield insulation pattern 173 that fills the second opening region SPHb may have a substantially same shape as the second opening region SPHb on a plan.

For example, in an embodiment the second portion 173b of the shield insulation pattern 173 may intersect the first portion 173a of the shield insulation pattern 173 and the bit lines BL to extend in the first direction X and have a line shape on a plane. Additionally, the second portion 173b of the shield insulation pattern 173 may be disposed to be spaced apart from each other in the second direction Y, which is the elongation direction of the bit lines BL, with the shield pattern SP interposed therebetween.

The second portion 173b of the shield insulation pattern 173 may overlay the bit lines BL in the third direction Z in the cell array region CAR and the first connection regions WCR. The second portion 173b of the shield insulation pattern 173 and the lower surface of the bit lines BL may be disposed to be spaced apart in the third direction Z, with the spacer insulation layer 171 interposed therebetween.

In some embodiments, the opening pattern SPH may include an air gap. For example, the opening pattern SPH may include the air gap that is at least one region of the first opening region SPHa and the second opening region SPHb. For example, the first opening region SPHa disposed between the adjacent bit lines BL may include the air gap, and the second opening region SPHb may be filled with the shield insulation pattern 173. Accordingly, the first portion SPa and the air gap of the shield pattern SP may be alternately disposed along the second direction Y between the adjacent bit lines BL.

As another example, some regions of the first opening region SPHa may include the air gap while some of the remaining regions may be filled with the shield insulation pattern 173, and the second opening region SPHb may be filled with the shield insulation pattern 173.

As another example, the first opening region SPHa may include the air gap, a portion of the second opening region SPHb may be filled with the shield insulation pattern 173, and the remaining portion may include the air gap.

The shield insulation pattern 173 may include an insulating material. For example, in an embodiment the shield insulation pattern 173 may include at least any of silicon oxide, silicon nitride, silicon oxynitride, a low dielectric constant (low-k) material such as SiOCN, SiOC, SiBN, SiBCN, SiBCON, or combination thereof. However, the insulating material included in shield insulation pattern 173 is not necessarily limited thereto and the materials of the shield insulation pattern 173 may vary.

As the shield pattern SP disposed between the adjacent bit lines BL includes the plurality of opening pattern SPH, the parasitic capacitance that occurs between the shield pattern SP and bit line BL may be reduced and simultaneously the coupling capacitance caused by the mutual interference between the adjacent bit lines BL may be reduced, thereby increasing a sensing margin of the bit lines BL.

In addition, by forming the plurality of opening pattern SPH by patterning the shield pattern SP for the total sum of the areas of the shield pattern SP disposed between adjacent bit lines BL to be substantially the same as each other, the parasitic capacitance and the coupling capacitance may be simultaneously controlled and simultaneously the sensitivity deviation of the signal may be reduced in each of plurality of bit lines BL.

In an embodiment, the capping insulation layer 175 may have a substantially uniform thickness and cover the shield pattern SP and the shield insulation pattern 173. In an embodiment, the capping insulation layer 175 may include, for example, a silicon oxide layer, a silicon nitride layer, a silicon oxynitride layer, and/or a low dielectric layer. However, embodiments of the present disclosure are not necessarily limited thereto.

The capping insulation layer 175 may be in direct contact with the spacer insulation layer 171 in the second connection regions BCR. The capping insulation layer 175, as shown in FIG. 5, may cover the ends of the shield pattern SP in the first connection regions WCR. For example, the capping insulation layer 175 may cover the end of the second portion SPb of the shield pattern SP disposed in the first connection regions WCR.

The semiconductor device according to an embodiment may further include a planarized insulation layer 180 disposed on (e.g., disposed directly thereon) the capping insulation layer 175 and the substrate 200.

The planarized insulation layer 180 may have different thicknesses in the cell array region CAR and first and the second connection regions (WCR, BCR). In an embodiment, the planarized insulation layer 180 may be, for example, any one of insulating materials and silicon oxide layers formed using a spin on glass (SOG) technology.

The first active patterns AP1 and the second active patterns AP2 may be disposed on each bit line BL. The first active patterns AP1 and the second active patterns AP2 may be disposed alternately in the second direction Y.

The first active patterns AP1 may be separated from each other in the first direction X.

The first active patterns AP1 may be spaced apart with a regular interval. The second active patterns AP2 may be spaced apart from each other in the first direction X.

The second active patterns AP2 may be spaced apart with a regular interval. The first and second active patterns AP1 and AP2 may be arranged two-dimensionally along the first direction X and the second direction Y that intersect each other.

In an embodiment, the first active pattern AP1 and the second active pattern AP2 may each be composed of a single crystal semiconductor material. For example, the first active pattern AP1 and the second active pattern AP2 may each be composed of single crystal silicon.

The first active pattern AP1 and the second active pattern AP2 may each have a length in the first direction X, a width in the second direction Y, and a height in the third direction Z. The first active pattern AP1 and the second active pattern AP2 may each have a substantially uniform width. For example, the first active pattern AP1 and the second active pattern AP2 may each have the substantially equivalent width (e.g., a substantially equal width) on the first and second surfaces opposing each other in the third direction Z, which is the vertical direction. Additionally, the width of the first active pattern AP1 may be substantially the same as the width of the second active pattern AP2.

The width of first active pattern AP1 and the width of second active pattern AP2 may range from several nm to tens of nm. For example, in an embodiment the width of first active pattern AP1 and the width of second active pattern AP2 may be in a range of about 1 nm to about 30 nm. For example, the width of the first and second active patterns AP1, AP2 may be in a range of about 1 nm to about 10 nm. However, embodiments of the present disclosure are not necessarily limited thereto. The length of each of the first and second active patterns AP1 and AP2 may be larger than the line width of the bit line BL. For example, the length of each of the first and second active patterns AP1 and AP2 may be larger than the width of the bit line BL in the first direction X.

In an embodiment, referring to FIG. 4, the first and second active patterns AP1 and AP2 may each have first and second faces that face each other. For example, the first surfaces of the first and second active patterns AP1 and AP2 may be in direct contact with the polysilicon layer 161 of the bit line BL. However, in some embodiments in which the polysilicon layer 161 is omitted, the first and second active patterns AP1, AP2 may be in direct contact with the metal layer 163 of the bit line BL.

The first and second active patterns AP1 and AP2 may each include a first side surface and a second side surface that face each other in the second direction Y. The first side surface of the first active pattern AP1 may be adjacent to the first word line WL1 (e.g., in the second direction Y), and the second side surface of the second active pattern AP2 may be adjacent to the second word line WL2 (e.g., in the second direction Y).

The first and second active patterns AP1 and AP2 may each include a first dopant region SDR1 adjacent to the bit line BL, a second dopant region SDR2 adjacent to the contact pattern BC, and a channel region CHR between the first and second dopant regions SDR1 and SDR2. The first and second dopant regions SDR1 and SDR2 are regions in which a dopant is doped within the first and second active patterns AP1 and AP2, and the dopant concentration in the first and second active patterns AP1 and AP2 may be greater than the dopant concentration in the channel region CHR.

However, in some embodiments, each of the first active pattern AP1 and the second active pattern AP2 may not include at least one of the first dopant region SDR1 and the second dopant region SDR2.

In an embodiment, the channel regions CHR of the first and second active patterns AP1 and AP2 may be controlled by the first and second word lines WL1 and WL2 and the back gate electrodes BG during the operation of the semiconductor device. Since the first and second active patterns AP1 and AP2 are composed of a single crystal semiconductor material, a leakage current characteristic of the semiconductor memory device may be increased.

Each back gate electrode BG may be disposed between the first active pattern AP1 and the second active pattern AP2, which are adjacent to each other in the second direction Y. For example, the first active pattern AP1 may be disposed on one side of each back gate electrode BG, and the second active pattern AP2 may be disposed on the other side of each back gate electrode BG. In an embodiment, the height along the third direction Z of the back gate electrode BG may be less than the height along the third direction Z of the first and second active patterns AP1 and AP2.

In an embodiment, the back gate electrode BG may include a conducting material. For example, the back gate electrode BG may include at least one of a doped polysilicon, a conductive metal nitride, a conductive metal silicon nitride, a metal nitride, a conductive metal silicide, a conductive metal oxide, a two-dimensional material, and a metal. However, embodiments of the present disclosure are not necessarily limited thereto.

The back gate electrodes BG may be applied with a negative voltage when the semiconductor device operates, and may increase the threshold voltage of the vertical channel transistor. In other words, as the vertical channel transistor is reduced, the threshold voltage decreases, preventing the leakage current characteristic from being deteriorated.

For example, referring to FIG. 4, the back gate electrode BG may include the first surface adjacent to the bit line BL and the second surface adjacent to the contact pattern BC. The first and second surfaces of the back gate electrode BG may be disposed at the different levels from the first and second surfaces of the first and second active patterns AP1 and AP2.

The semiconductor device according to an embodiment may further include a back gate separation pattern 111, a back gate insulation pattern 113, and a back gate capping pattern 115.

The back gate separation pattern 111 may be disposed between the first and second active patterns AP1 and AP2, which are adjacent to each other in the second direction Y. The back gate separation pattern 111 may be disposed between the second dopant regions SDR2 of the first and second active patterns AP1 and AP2. The back gate separation pattern 111 may extend parallel to the back gate electrodes BG in the first direction X.

In an embodiment, the back gate separation pattern 111 may include, for example, a silicon oxide layer, a silicon oxynitride layer, or silicon nitride. The back gate separation pattern 111 may be disposed at a substantially equivalent level to a gate capping pattern 143, which will be described later. In an embodiment, the back gate separation pattern 111 may be formed of the same material as the gate capping pattern 143.

The back gate insulation pattern 113 may be disposed between the back gate electrode BG and the first active pattern AP1 (e.g., in the second direction Y) and between the back gate electrode BG and the second active pattern AP2 (e.g., in the second direction Y). The back gate insulation pattern 113 may be disposed between the back gate separation pattern 111 and the first active pattern AP1 and between the back gate separation pattern 111 and the second active pattern AP2.

In an embodiment, the back gate insulation pattern 113 may include vertical portions covering both sides of the back gate electrode BG and a horizontal portion connecting the vertical portions. The horizontal portion of back gate insulation pattern 113 may be positioned closer to the contact pattern BC than the bit line BL and cover the second surface of the back gate electrode BG.

In an embodiment, the back gate insulation pattern 113 may include, for example, a silicon oxide layer, a silicon oxynitride layer, a high dielectric constant insulation layer having a higher dielectric constant than the silicon oxide layer, or a combination thereof.

The back gate capping pattern 115 may be disposed between the bit line BL and the back gate electrode BG (e.g., in the third direction Z). The back gate capping pattern 115 may be disposed between the first active pattern AP1 and the second active pattern AP2 adjacent in the second direction Y. In the back gate capping pattern 115, the bit line BL may extend to be parallel to the back gate electrode BG in the first direction X.

In an embodiment, the lower surface of the back gate capping pattern 115 may be in direct contact with the polysilicon layer 161 of the bit lines BL. The back gate capping pattern 115 may be disposed between the vertical portions of the back gate insulation pattern 113. In an embodiment, the thickness of the back gate capping pattern 115 between the bit lines BL may be different from the thickness of the back gate capping pattern 115 on the bit lines BL.

The back gate capping pattern 115 may be formed of an insulating material. For example, in an embodiment the back gate capping pattern 115 may include at least one of a silicon oxide layer, a silicon oxynitride layer, and a silicon nitride. However, embodiments of the present disclosure are not necessarily limited thereto.

The first word line WL1 and the second word line WL2 may be disposed on the bit line BL.

In an embodiment, the back gate electrodes BG do not overlap with the shield insulation pattern 173 filled within the opening pattern SPH in the third direction Z, and the first and second word lines WL1 and WL2 may overlap with the shield insulation pattern 173 filled within the opening pattern SPH in the third direction Z. However, the arrangement relationship between the back gate electrodes BG and the shield insulation pattern 173 filled within the opening pattern SPH and the arrangement relationship between the first and second word lines WL1 and WL2 and the shield insulation pattern 173 filled within the opening pattern SPH are not necessarily limited thereto and may vary.

Each of the first word line WL1 and the second word line WL2 may extend in the first direction X. The first word line WL1 and the second word line WL2 may be arranged alternately in the second direction Y.

The first word line WL1 may be disposed on one side of the first active pattern AP1 (e.g., in the second direction Y), and the second word line WL2 may be disposed on the other side of the second active pattern AP2 (e.g., in the second direction Y). The first active patterns AP1 and the second active patterns AP2 may be disposed between the first word line WL1 and the second word line WL2 adjacent in the second direction Y.

The first word line WL1 and the second word line WL2 may be spaced apart from the bit line BL and the contact pattern BC in the third direction Z. The first word line WL1 and the second word line WL2 may be disposed between the bit line BL and the contact pattern BC (e.g., in the third direction Z).

Each first word line WL1 and second word line WL2 may have a width in the second direction Y. For example, the width of the first word line WL1 and the width of the second word line WL2 disposed between the bit lines BL may be different from the width of the first word line WL1 and the width of the second word line WL2 overlapping the bit line BL in the third direction Z. However, embodiments of the present disclosure are not necessarily limited thereto, and the widths of the first and second word lines WL1 and WL2 may vary.

The first and second word lines WL1 and WL2 adjacent to each other may include the side surfaces facing each other. The first and second word lines WL1 and WL2 may each include the first surface adjacent to the bit line BL and the second surface adjacent to the contact pattern BC.

The first surfaces of first and second word lines WL1 and WL2 may have various shapes. For example, in some embodiments, the first and second word lines WL1 and WL2 each may have an L-shaped cross-section. However, embodiments of the present disclosure are not necessarily limited thereto.

In an embodiment, the height of the first and second word lines WL1 and WL2 in the third direction Z may be less than the height of first and second active patterns AP1 and AP2 in the third direction Z. The height of the first and second word lines WL1 and WL2 in the third direction Z may be less than or substantially equal to the height Z of the back gate electrodes BG in the third direction.

The semiconductor device according to an embodiment may further include separation insulation patterns 300 disposed in the first connection regions WCR.

The separation insulation pattern 300 may penetrate the first and second word lines WL1 and WL2 in each of the first connection regions WCR in the third direction Z which is the vertical direction. The first and second word lines WL1 and WL2 may be electrically separated and insulated from each other by the separation insulation patterns 300 in the first connection regions WCR.

In an embodiment, the first and second word lines WL1 and WL2 may include a conducting material, for example, at least one of a doped polysilicon, a conductive metal nitride, a conductive metal silicon nitride, a metal carbon nitride, a conductive metal silicide, a conductive metal oxide, a two-dimensional material, and a metal. However, embodiments of the present disclosure are not necessarily limited thereto.

The semiconductor device according to an embodiment may further include a gate insulation pattern GOX, a gate capping pattern 143, first and second etch stop layers 131 and 141, a first gate separation pattern 153, a second gate separation pattern 155, third and fourth etch stop layers 211 and 213, an interlayer insulating layer 231.

In an embodiment, the gate insulation patterns GOX may be disposed between the first word line WL1 and the first active pattern AP1, and the second word line WL2 and the second active patterns AP2. The gate insulation patterns GOX may extend parallel to the first and second word lines WL1 and WL2 in the first direction X.

In an embodiment, the gate insulation pattern GOX may be composed of a silicon oxide layer, a silicon oxynitride layer, a high dielectric layer with a higher dielectric constant than the silicon oxide layer, or a combination thereof. The high dielectric layer may be composed of a metal oxide or a metal oxide nitride. For example, the high dielectric layer that may be used as the gate insulation pattern GOX may be composed of HfO₂, HfSiO, HfSiON, HfTaO, HfTiO, HfZrO, ZrO₂, Al₂O₃, or combination thereof, but it is not necessarily limited thereto.

For example, referring to FIG. 4, the gate insulation pattern GOX may extend along the first side surface of the first active pattern AP1 and extend along the second side surface of the second active pattern AP2. In an embodiment, the gate insulation pattern GOX may have a substantially uniform thickness and may be disposed conformally.

Each of the gate insulation patterns GOX may include the vertical portion adjacent to the first and second active patterns AP1 and AP2 and the horizontal portion protruding from the vertical portion in the first direction X. A pair of first and second word lines WL1 and WL2 may be disposed on the horizontal portion of each of the gate insulation patterns GOX. For example, the gate insulation pattern GOX between the first active pattern AP1 and the first word line WL1 may be separated from the gate insulation pattern GOX between the second active pattern AP2 and the second word line WL2.

The gate capping pattern 143 may be disposed between the horizontal portion of the gate insulation pattern GOX and the contact pattern BC (e.g., in the third direction Z). In an embodiment, the gate capping pattern 143 may include, for example, silicon oxide.

First and second etch stop layers 131 and 141 may be disposed between the second dopant regions SDR2 of the first and second active patterns AP1 and AP2 and the gate capping pattern 143.

The first gate separation pattern 153 and the second gate separation pattern 155 may be disposed on the bit line BL. The first gate separation pattern 153 and the second gate separation pattern 155 may be disposed between the bit line BL and the gate insulation pattern GOX. In an embodiment, the first gate separation pattern 153 and the second gate separation pattern 155 may be in contact with the bit line BL. The first gate separation pattern 153 and the second gate separation pattern 155 may extend in the first direction X between the first word line WL1 and the second word line WL2.

The first gate separation pattern 153 may be disposed between the second gate separation pattern 155 and the first and second word lines WL1 and WL2. In an embodiment, the first gate separation pattern 153 may be in direct contact with the first and second word lines WL1 and WL2. The first gate separation pattern 153 may have a substantially uniform thickness and be disposed conformally along the gate insulation pattern GOX and the side surface of the first and second word lines WL1 and WL2.

The first gate separation pattern 153 and the second gate separation pattern 155 may each include an insulating material.

The third and fourth etch stop layers 211 and 213 and the interlayer insulating layer 231 may cover the second surfaces of the first and second active patterns AP1 and AP2 in the cell array region CAR. The interlayer insulating layer 231 may extend to the first and second connection regions WCR and BCR, and may cover an upper surface of an isolation layer STI described later and a surrounding gate electrode PG described later. Each of the third and fourth etch stop layers 211 and 213 and the interlayer insulating layer 231 may include an insulating material.

The semiconductor device according to an embodiment may include contact patterns BC, landing pads LP, a pad separation insulation pattern 245, and an upper insulation layer 270.

The contact patterns BC may penetrate (e.g., in the third direction Z) the third and fourth etch stop layers 211 and 212 and the interlayer insulating layer 231. The contact patterns BC may be connected to the first and second active patterns AP1 and AP2, respectively. The contact patterns BC may be connected to the second surfaces of the first and second active patterns AP1 and AP2. For example, the contact patterns BC may be in contact with the second dopant region SDR2 of the first and second active patterns AP1 and AP2, respectively. The contact patterns BC may have a lower width that is greater than the upper width on a cross-section. The contact patterns BC adjacent to each other may be separated from each other by the separation insulation patterns 245.

Each contact pattern BC may have various shapes on a plane, such as circular, oval, rectangular shape, square, rhombus, and hexagon. However, embodiments of the present disclosure are not necessarily limited thereto.

The contact pattern BC may include a conducting material. For example, in an embodiment the contact pattern BC may include at least one of a doped polysilicon, a conductive metal nitride, a conductive metal silicon nitride, a metal carbon nitride, a conductive metal silicide, a conductive metal oxide, two-dimensional material and metal.

The landing pads LP may be disposed on the contact pattern BC. In an embodiment, the landing pads LP may have various shapes in plan, such as circular, oval, rectangular shape, square, rhombus, and hexagon. However, embodiments of the present disclosure are not necessarily limited thereto.

The pad separation insulation patterns 245 may be disposed between the landing pads LP. In an embodiment, the landing pads LP may be arranged in a matrix pattern along the first direction X and the second direction Y on a plane. The upper surface of the landing pad LP may be substantially coplanar with the upper surface of the pad separation insulation pattern 245 (e.g., in the third direction Z).

In an embodiment, the landing pad LP may include a conducting material, for example, a doped polysilicon, a conductive metal nitride, a conductive metal silicon nitride, a metal carbon nitride, a conductive metal silicide, a conductive metal oxide, a two-dimensional material, and a metal.

In the cell array region CAR, the data storage patterns DSP may be respectively disposed on the landing pads LP. The data storage patterns DSP may be electrically connected to the first and second active patterns AP1 and AP2, respectively.

In an embodiment, the data storage patterns DSP, as shown in FIG. 1, may be arranged in a matrix pattern along the first direction X and the second direction Y. The data storage patterns DSP may overlap completely or partially with the landing pads LP in the third direction Z. In an embodiment, the data storage patterns DSP may be in direct contact with the entirety of or a portion of the upper surface of the landing pads LP.

For example, in an embodiment the data storage patterns DSP may be a capacitor. The data storage patterns DSP may include a capacitor dielectric layer 253 interposed between the storage electrodes 251 and the plate electrode 255. In this embodiment, the storage electrode 251 may be in direct contact with the landing pad LP.

In an embodiment, the storage electrode 251 may have various shapes in a plane, such as circular, oval, rectangular shape, square, rhombus, and hexagon. However, embodiments of the present disclosure are not necessarily limited thereto.

The data storage patterns DSP may overlap completely or partially with the landing pads LP in the third direction Z. The data storage patterns DSP may be in direct contact with entirety of or a portion of the upper surface of the landing pads LP. The storage electrodes 251 may penetrate the sixth etch stop layer 247 (e.g., in the third direction Z). The sixth etch stop layer 247 may include an insulating material.

In contrast, the data storage patterns DSP may be a variable resistor pattern that can be switched between two resistance states by an electrical pulses applied to memory elements. For example, in an embodiment the data storage patterns DSP are phase-change materials having a crystal state that changes depending on an amount of a current, such as perovskite compounds, transition metal oxides, magnetic materials, ferromagnetic materials, or antiferromagnetic materials.

In an embodiment, a memory cell contact plug connected to the plate electrode 255 may be disposed on the data storage patterns DSP.

The upper insulation layer 270 may be disposed on (e.g., disposed directly thereon) the data storage patterns DSP. The upper insulation layer 270 may cover the plate electrode 255, and the upper insulation layer 270 may include an insulating material.

The semiconductor device according to an embodiment may further include a surrounding active pattern 110, a surrounding gate insulating layer 215, and a surrounding gate electrode PG disposed on the substrate 200 in the first and second connection regions WCR and BCR.

In an embodiment, the surrounding active pattern 110 may include the same single crystal semiconductor material as the first and second active patterns AP1 and AP2 of the cell array region CAR. The surrounding active pattern 110 may have a first surface adjacent to the substrate 200 and a second surface opposing it.

The first surface of the surrounding active pattern 110 may be substantially coplanar with the first surfaces of the first and second active patterns AP1 and AP2. The second surface of the surrounding active pattern 110 may be substantially coplanar with the second surfaces of the first and second active patterns AP1 and AP2.

The isolation layer STI may be disposed on the substrate 200 in the first and second connection regions WCR and BCR. The isolation layer STI may penetrate and surround the surrounding active pattern 110.

The peripheral circuit transistors may be disposed on the second surface of the surrounding active pattern 110. In an embodiment, the peripheral circuit transistors may configure, for example, row and column decoders, sense amplifiers, or control logics.

For example, the surrounding gate insulating layer 215 may be disposed on the second surface of the surrounding active pattern 110, and the surrounding gate electrode PG may be disposed on the surrounding gate insulating layer 215.

In an embodiment, the surrounding gate electrode PG may include a surrounding conductive pattern 221, a surrounding metal pattern 223, and a surrounding mask pattern 225 (e.g., consecutively disposed in the third direction Z).

The semiconductor device according to an embodiment may further include word line contact plugs connected to the first and second word lines WL1 and WL2 in the first connection regions WCR, bit line contact plugs PCPa connected to the bit lines BL in the second connection regions BCR, and shield contact plugs PCPb connected to the shield pattern SP in the first connection regions WCR.

For example, the surrounding contact plugs PCPa, PCPb, and PCPc may include a bit line contact plug PCPa penetrating the fifth etch stop layer 233, the interlayer insulating layer 231, and the isolation layer STI to be connected to the end portion of the bit line BL, such as the end portion of the metal layer 163, a shield contact plug PCPb connected to the end portion of the shield pattern SP, and a surrounding contact plug PCPc connected to the source/drain region of the surrounding transistor

The bit line contact plug PCPa may be connected to the end portion of the bit lines BL by penetrating (e.g., in the third direction Z) the isolation layer STI in the second connection regions BCR. The shield contact plugs PCPb may be connected to the end portion of the shield pattern SP by passing through (e.g., in the third direction Z) the isolation layer STI in the first connection region WCR. The surrounding contact plug PCPc may be connected to the peripheral circuit transistors in the second connection regions BCR. In an embodiment, the surrounding contact plug PCPc may be connected to the peripheral circuit transistors in the first connection regions WCR.

The bit line contact plug PCPa may be connected to the first surrounding wire 241a, the shield contact plug PCPb may be connected to the second surrounding wire 241b, and the surrounding contact plug PCPc may be connected to the third surrounding wire 241c.

The pad separation insulation pattern 245 may insulate the first and second surrounding wires 241a and 241b from each other in the first and second connection regions WCR and BCR.

The peripheral circuit insulation layer 263 and the upper insulation layer 270 may be sequentially disposed (e.g., in the third direction Z) on the first, second, and third surrounding wires 241a, 241b, and 241c. A sixth etch stop layer 247 may be disposed between the peripheral circuit insulation layer 263 and the first, second, and third surrounding wires 241a, 241b, and 241c (e.g., in the third direction Z).

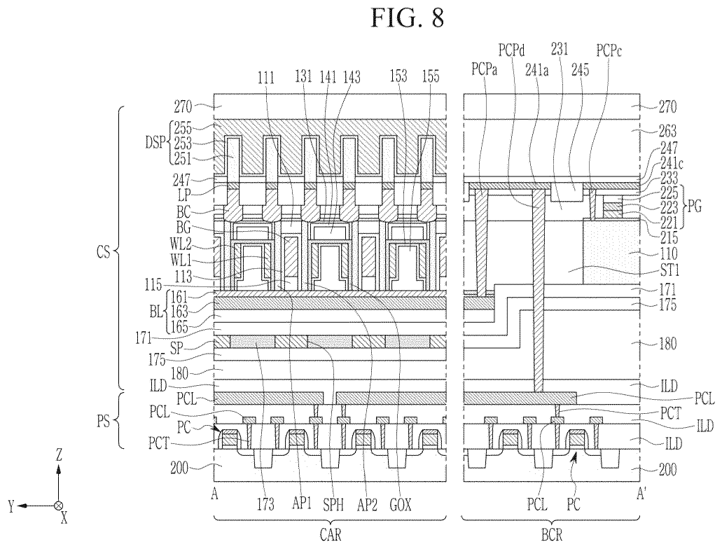

Hereinafter, the semiconductor devices according to various embodiments are described with reference to FIG. 8 to FIG. 30. In the following embodiment, the same configuration as the previously described embodiment will be referred to by the same reference numeral, the redundant description of an identical or similar element may be omitted or simplified, and the differences will be mainly explained for economy of description.

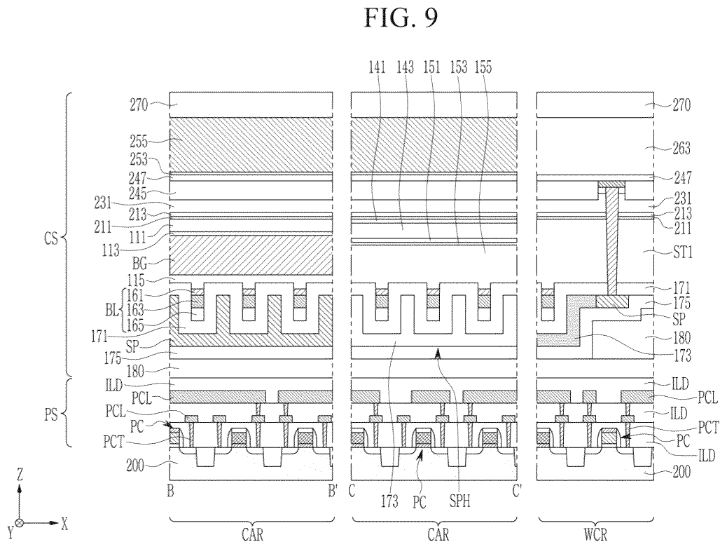

FIG. 8 is a cross-sectional view taken along a line A-A′ of FIG. 1 according to some embodiments. FIG. 9 is a cross-sectional view showing a cross-section taken along a line B-B′ and a line C-C′ of FIG. 1 and a cross-section of a word line connection region according to some embodiments.

According to an embodiment shown in FIG. 8 and FIG. 9, the semiconductor device may include a peripheral circuit structure PS, and a cell array structure CS connected to the peripheral circuit structure PS.

In an embodiment, the cell array structure CS may be disposed on (e.g., disposed directly thereon in the third direction Z) the peripheral circuit structure PS. In the cell array structure CS, referring to FIG. 1 to FIG. 7, as described above, a vertical channel transistor (VCT) may be provided as a cell transistor for each memory cell and a capacitor may be provided as a data storage element for each memory cell.

The peripheral circuit structure PS may be disposed over the cell array region CAR and the first and second connection regions BCR and WCR. For example, a portion of the peripheral circuit structure PS may be disposed in the cell array region CAR of the substrate 200, and the remainder of the peripheral circuit structure PS may be disposed in the first and second connection regions BCR and WCR of the substrate 200.

The peripheral circuit structure PS may be disposed between the substrate 200 and the cell array structure CS. In an embodiment, the substrate 200 may be, for example, a single crystal silicon substrate.

The peripheral circuit structure PS may be disposed between the substrate 200 and the planarized insulation layer 180 of the cell array structure CS (e.g., in the third direction Z). In an embodiment, the peripheral circuit structure PS may include core and peripheral circuits PC formed on a substrate 200, peripheral circuit insulation layers ILD covering the core and peripheral circuits PC and disposed between the substrate 200 and the planarized insulation layer 180, and surrounding metal structures PCT and PCL disposed within the peripheral circuit insulation layers ILD.

The core and peripheral circuits PC may include row and column decoders, sense amplifiers, a control logic, etc. For example, the core and peripheral circuits PC may include NMOS and PMOS transistors integrated on the substrate 200. However, embodiments of the present disclosure are not necessarily limited thereto and the types of the transistors of the peripheral circuit PC disposed on the substrate 200 of the cell array region CAR may vary, such as depending on the design arrangement of the semiconductor device.

The peripheral circuit insulation layer ILD may cover the core and peripheral circuits PC and the surrounding metal structures PCL and PCT on the substrate 200. The peripheral circuit insulation layer ILD may include multi-layered insulation layers. In an embodiment, the peripheral circuit insulation layer ILD may include, for example, a silicon oxide layer, a silicon nitride layer, a silicon oxynitride layer, and/or a low dielectric layer.

The surrounding metal structures PCT and PCL may include at least two metal patterns PCL and metal plugs PCT connected to the metal patterns PCL.

The core and peripheral circuits PC may be electrically connected to the bit lines BL of the cell array structure CS through the surrounding metal structures PCL and PCT, the first surrounding wires 241a, the surrounding contact plugs PCPd.

The cell array structure CS, as described above, may include memory cells including a vertical channel transistor (VCT).

The vertical channel transistor may refer to a structure in which the channel length extends in a vertical direction with respect to the upper surface of the substrate 200. In an embodiment, the cell array structure CS may include a plurality of bit lines BL, a shield pattern SP, first and second active patterns AP1 and AP2, first and second word lines WL1 and WL2, and data storage patterns DSP.

The bit lines BL of the cell array structure CS may be disposed adjacent to the peripheral circuit structure PS. Since the bit lines BL are disposed adjacent to the peripheral circuit structure PS, the electrical connection path between the bit lines BL and the core and peripheral circuits PTR may be reduced.

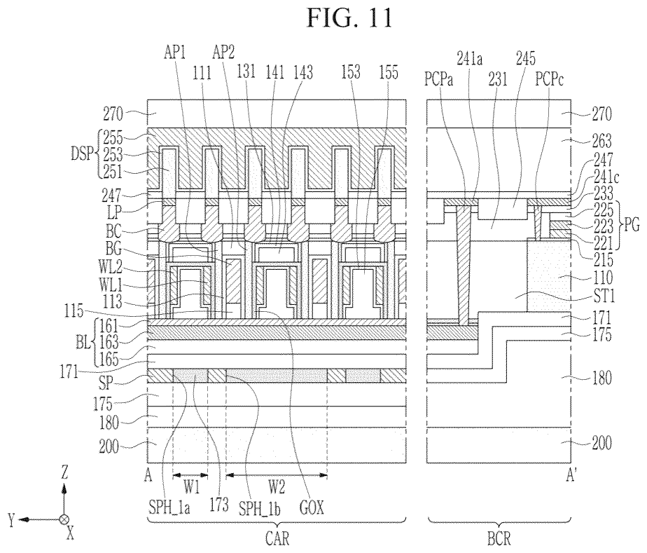

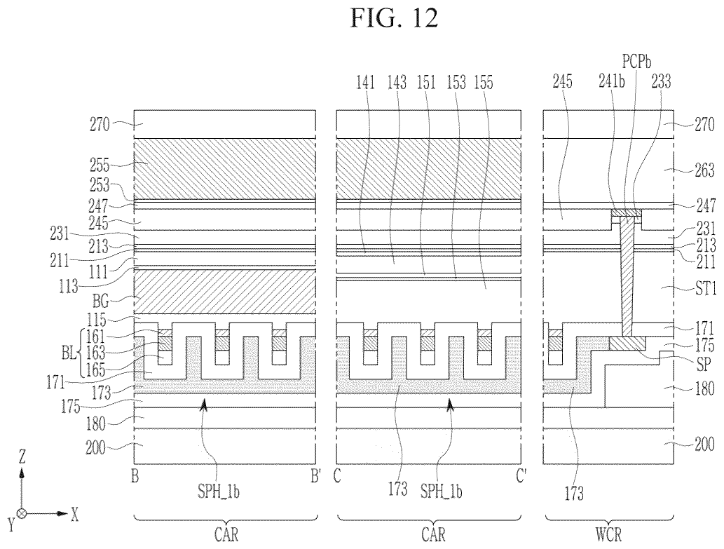

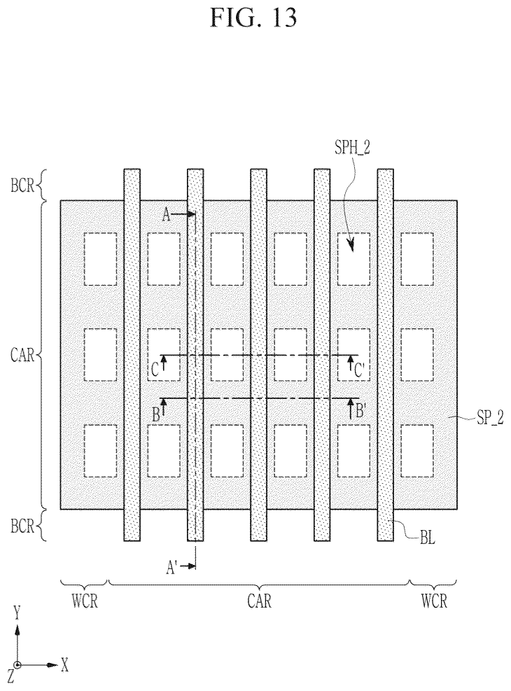

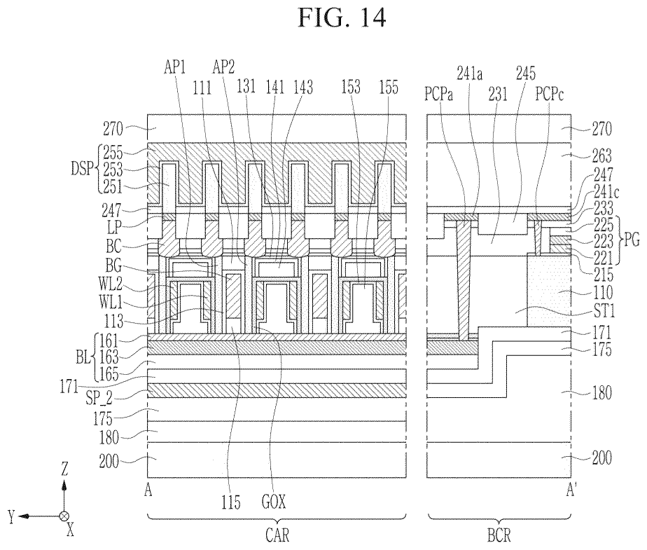

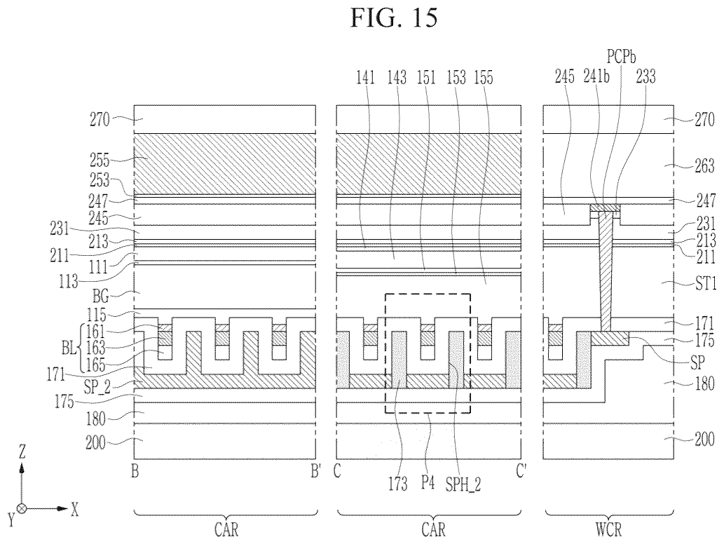

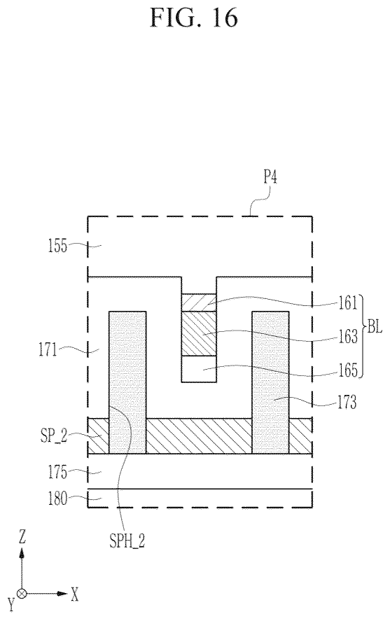

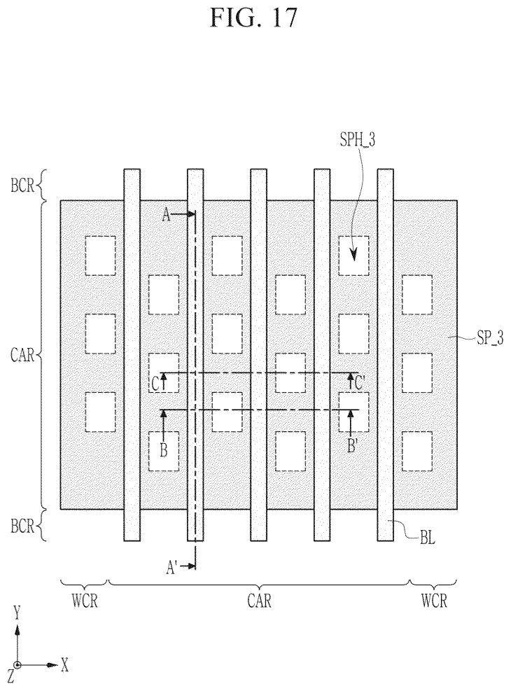

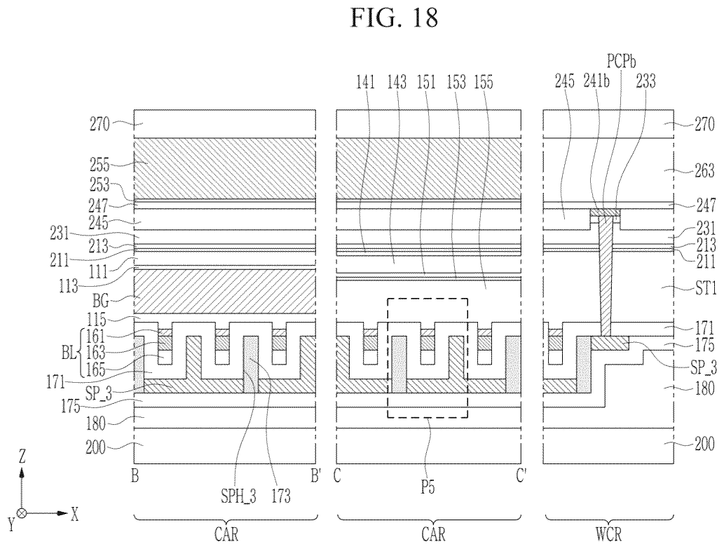

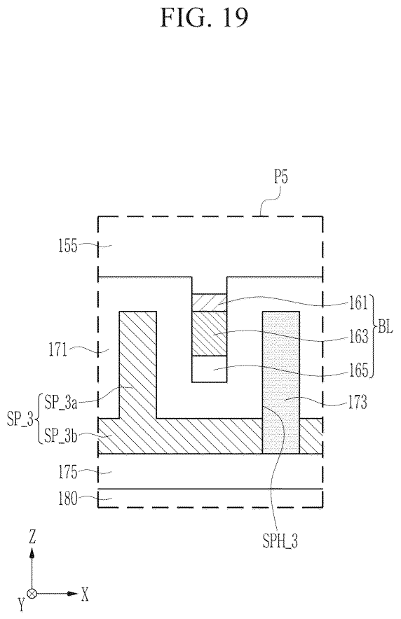

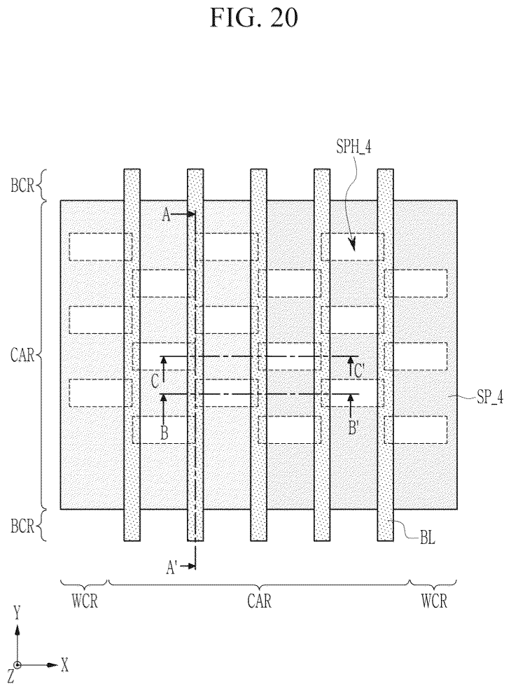

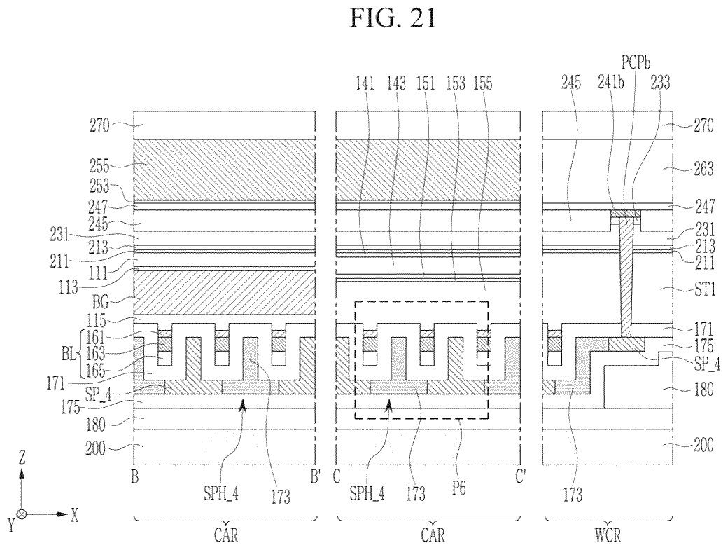

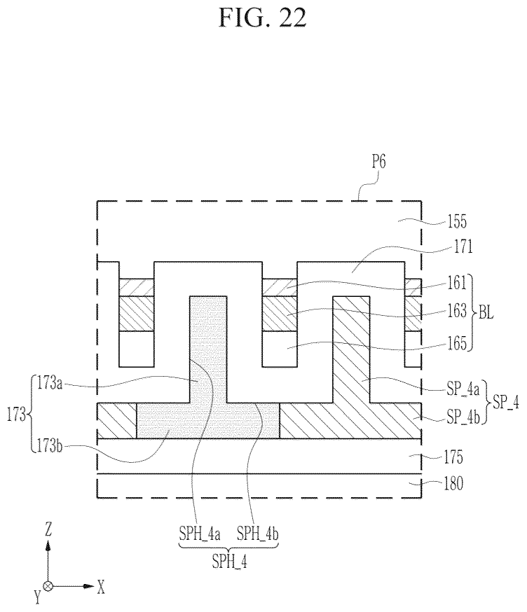

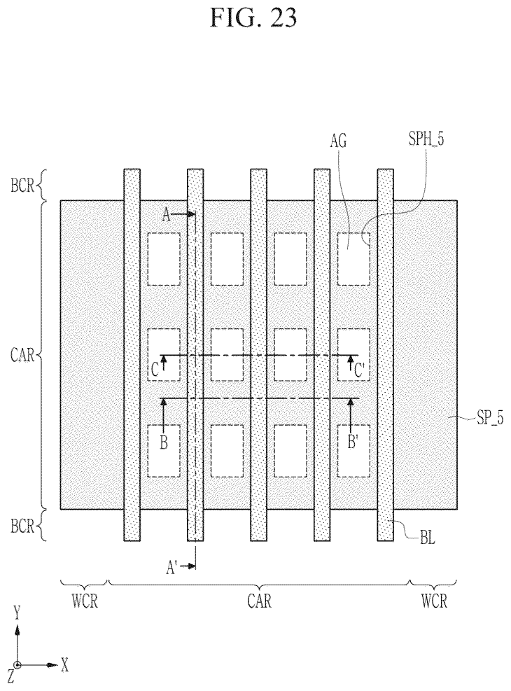

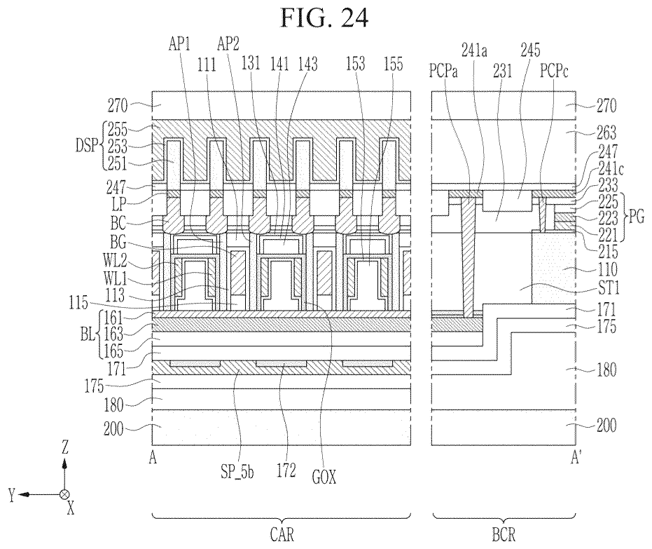

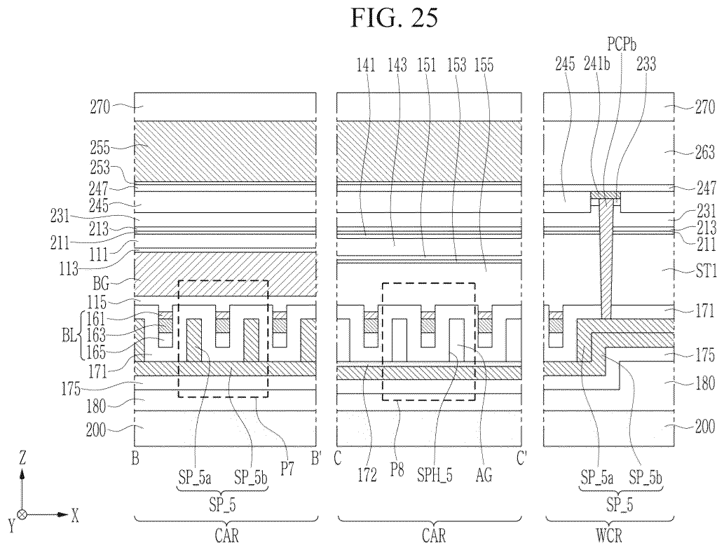

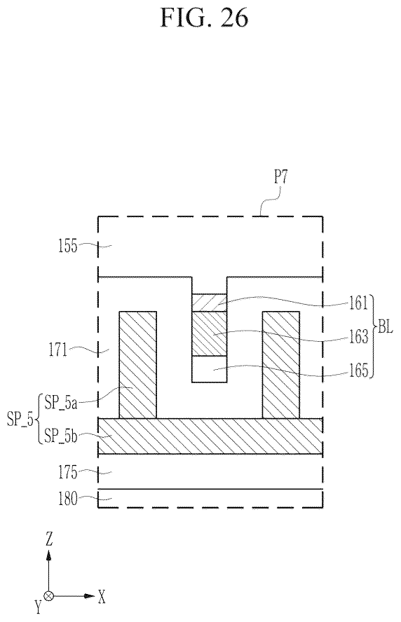

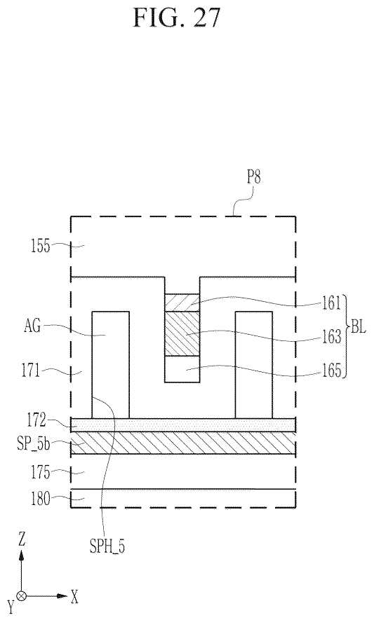

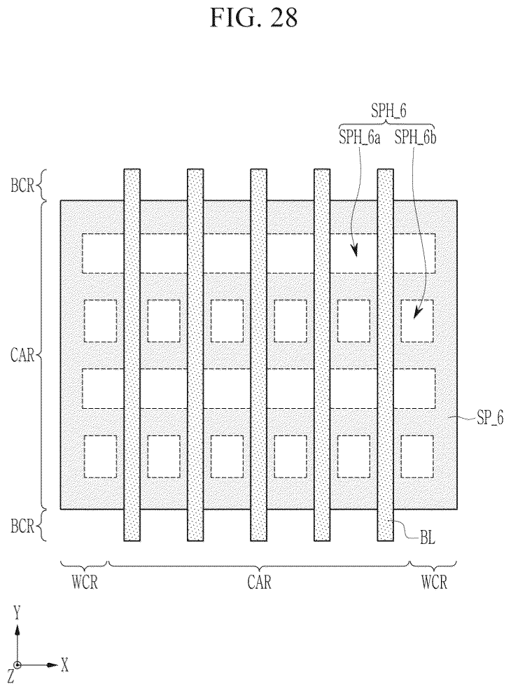

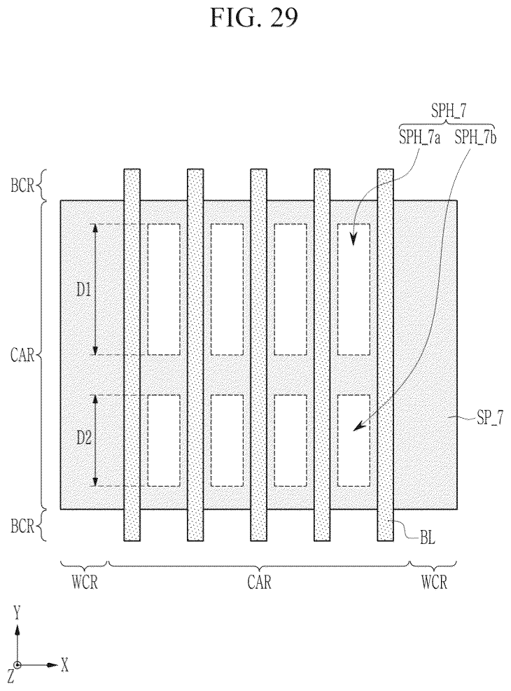

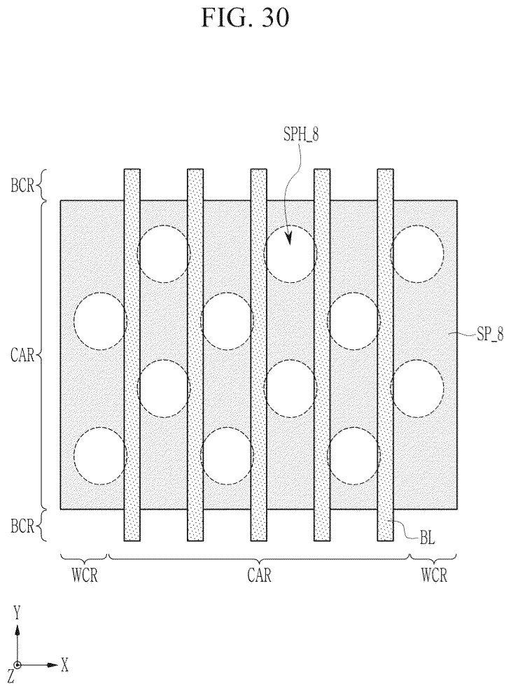

FIG. 10, FIG. 13, FIG. 17, FIG. 20, FIG. 23, and FIG. 28 to FIG. 30 are layout views to explain semiconductor devices according to some embodiments. FIG. 11, FIG. 12, FIG. 14, FIG. 15, FIG. 18, FIG. 21, FIG. 24, and FIG. 25 are cross-sectional views to explain semiconductor devices according to some embodiments. FIG. 16, FIG. 19, FIG. 22, FIG. 26, and FIG. 27 are partial enlarged views to explain semiconductor devices according to some embodiments.

In detail, FIG. 10, FIG. 13, FIG. 17, FIG. 20, FIG. 23, and FIG. 28 to FIG. 30 are plan views showing a bit line and a shield pattern of FIG. 1. FIG. 11, FIG. 14, and FIG. 24 are cross-sectional views taken along a line A-A′ of FIG. 10, FIG. 13, and FIG. 23 according to some embodiment, respectively. FIG. 12, FIG. 15, FIG. 18, FIG. 21, and FIG. 25 are cross-sectional views showing cross-sections taken along a line B-B′ and a line C-C′ and cross-sections of a word line connection region of FIG. 10, FIG. 13, FIG. 17, FIG. 20, and FIG. 23, respectively. FIG. 16 is a partial enlarged view enlarging a region P4 of FIG. 15. FIG. 19 is a partial enlarged view enlarging a region P5 of FIG. 8. FIG. 22 is a partial enlarged view enlarging a region P6 of FIG. 21. FIG. 26 is a partial enlarged view enlarging a region P7 of FIG. 25. FIG. 27 is a partial enlarged view enlarging a region P8 of FIG. 25.

According to embodiments shown in FIG. 10 to FIG. 12, the shield pattern SP_1 may include a plurality of opening patterns SPH_1 disposed in the cell array region CAR and the first connection regions WCR and having different areas from each other.

The plurality of opening patterns SPH_1 intersects the plurality of bit lines BL on a plane and extends in one side and the other side of the first direction X, and each of the plurality of opening pattern SPH may overlap the plurality of bit lines BL in the third direction Z.

Unlike the embodiment shown in FIG. 2 and FIG. 3, as shown in FIG. 10, the plurality of opening patterns SPH_1 according to an embodiment may include a first opening pattern SPH_1a and a second opening pattern SPH_1b having different areas from each other.

The first opening pattern SPH_1a and the second opening pattern SPH_1b each extend in the first direction X and may have a line shape on a plane. The first opening pattern SPH_1a and the second opening pattern SPH_1b are spaced apart in the second direction Y and may be arranged alternately in the second direction Y. However, embodiments of the present disclosure are not necessarily limited thereto and the arrangement form of the first opening pattern SPH_1a and the second opening pattern SPH_1b may vary. For example, the first opening pattern SPH_1a and the second opening pattern SPH_1b may each be arranged consecutively in the second direction Y.

The areas of the first opening pattern SPH_1a and the second opening pattern SPH_1b may be different from each other. In an embodiment, the lengths of the first opening pattern SPH_1a and the second opening pattern SPH_1b along the first direction are substantially equivalent (e.g., equal to each other) and the widths of the first opening pattern SPH_1a and the second opening pattern SPH_1b along the second direction Y are different from each other, thereby differentiating the areas.

For example, the width of the first opening pattern SPH_1a along the second direction Y has a first width W1, the width of the second opening pattern SPH_1b along the second direction Y has a second width W2. In an embodiment the first width W1 may be less than the second width W2.

As each of the plurality of opening patterns SPH_1 has the different area, the area of the shield insulation pattern 173 filling each of the plurality of opening patterns SPH_1 may be different from each other. For example, as shown in FIG. 11, the shield insulation pattern 173 is disposed to be spaced apart from each other in the second direction Y on the bit line BL, and the width of each shield insulation pattern 173 in the second direction Y may be different from each other. For example, the width in the second direction Y of the shield insulation pattern 173 filling the first opening pattern SPH1_a has a first width W1, and the width along the second direction Y of the shield insulation pattern 173 filling the second opening pattern SPH1_b has a second width W2. In an embodiment, the first width W1 may be less than the second width W2.

Unlike the embodiments shown in FIG. 3 and FIG. 5, as the width in the second direction Y of the second opening pattern SPH_1b is greater than the width in the second direction Y of the first opening pattern SPH_1a among the plurality of opening patterns SPH_1, the second opening pattern SPH_1b may be disposed to extend further in the second direction Y as compared to the first opening pattern SPH_1a, and the second opening pattern SPH_1b may overlap the back gate electrode BG in the third direction Z (e.g., the vertical direction). Accordingly, the shield insulation pattern 173 filling the second opening pattern SPH_1b may be disposed to overlap the back gate electrode BG in the third direction Z.

The shield pattern SP_2 according to embodiments shown in FIG. 13 to FIG. 16, unlike the shield pattern SP according to embodiments shown in FIG. 2, FIG. 3, and FIG. 5, may include a plurality of opening patterns SPH_2 disposed in the cell array region CAR and the first connection regions WCR. The plurality of opening patterns SPH_2 may be arranged in an island pattern on a plane (e.g., in a plane defined in the first and second directions X, Y).

For example, the plurality of opening patterns SPH_2 may be disposed between the bit lines BL and arranged in a matrix pattern along the first direction X and the second direction Y, accordingly, the plurality of opening patterns SPH_2 may be arranged in an island pattern on a plane. In FIG. 13, the planar shape and the size of each of the plurality of opening patterns SPH_2 is shown to be substantially equivalent to each other. However, embodiments of the present disclosure are not necessarily limited thereto. For example, in some embodiments, the planar shape and size of at least some of the plurality of opening patterns SPH_2 may be different from each other.

The plurality of opening patterns SPH_2 according to an embodiment, unlike embodiments shown in FIG. 2, FIG. 3, and FIG. 5, may be disposed between the bit lines BL in the cell array region CAR and disposed on the side surface of the bit lines BL in the first connection regions WCR. For example, each of the plurality of opening patterns SPH_2 may be disposed between the bit lines BL and on the side surface of the bit lines BL, and may not overlap the plurality of bit lines BL in the third direction Z (e.g., the vertical direction).

Accordingly, the shield pattern SP_2 may extend in the second direction Y, which is the elongation direction of the bit line BL, on the lower surface of the plurality of bit lines BL. In addition, the plurality of opening patterns SPH_2 are spaced apart from each other and arranged in parallel with the bit line BL interposed therebetween in the first direction, and the plurality of opening patterns SPH_2 disposed between the bit lines BL and on the side surface of the bit lines BL may be arranged side by side along the second direction Y.

Referring to FIG. 15 and FIG. 16, unlike embodiments shown in FIG. 2, FIG. 3, and FIG. 5, the opening patterns SPH_2 may be disposed on both sides of the bit lines BL, and the shield pattern SP_2 may be disposed on the lower surface of the bit lines BL. Each of the opening patterns SPH_2 may extend in the third direction Z by penetrating the shield pattern SP_2 disposed on the lower surface of the bit lines BL, and each of the opening patterns SPH_2 may be disposed within the gap region of the spacer insulation layer 171.

According to an embodiment, the shield insulation pattern 173 may be filled within the plurality of opening patterns SPH_2. One end of the shield insulation pattern 173 may be in direct contact with the spacer insulation layer 171, and the other end may be in direct contact with the capping insulation layer 175.

Accordingly, the shield insulation pattern 173 disposed on both lateral sides of the bit lines BL is disposed to be spaced apart from the bit line BL in the first direction via the spacer insulation layer 171, and the shield pattern SP_2 disposed on the lower surface of the bit lines BL may be disposed to spaced apart from the bit lines BL in the third direction Z via the spacer insulation layer 171 interposed therebetween.

In addition, the shield pattern SP_2 may be disposed between the shield insulation patterns 173 on the lower surface of the bit lines BL, and both ends of the shield pattern SP_2 may be in direct contact with the shield insulation pattern 173.

In FIG. 15 and FIG. 16, it is shown that the shield insulation pattern 173 is filled within the plurality of opening patterns SPH_2. However, embodiments of the present disclosure are not necessarily limited thereto. For example, in some embodiment, at least some of each of the plurality of opening patterns SPH_2 may include an air gap.

The shield pattern SP_3 according to embodiments shown in FIG. 17 to FIG. 19 may be disposed in the cell array region CAR and the first connection regions WCR, and may include a plurality of opening patterns SPH_3 arranged as an island pattern on a planar surface. However, the planar arrangement of the plurality of opening pattern SPH_3 according to an embodiment may be different from the planar arrangement of the plurality of opening patterns SPH_2 according to an embodiment shown in FIG. 13.

Specifically, the plurality of opening pattern SPH_3 according to an embodiment is arranged in an island pattern on a plane and may be arranged in a zigzag (e.g., an offset relationship) along the second direction Y with the bit lines BL interposed therebetween. In other words, as the plurality of opening patterns SPH_3 are disposed alternately along the second direction Y with the bit line BL interposed therebetween on a plane, the opening pattern SPH_3 disposed on one side of the first direction X of the bit line BL and the opening pattern SPH_3 disposed on the other side of the first direction may be arranged along the diagonal direction that intersects the first direction X and the second direction Y.

Additionally, the plurality of opening patterns SPH_3 disposed between the adjacent bit lines BL may be arranged side by side along the second direction Y. Accordingly, at least two adjacent bit lines BL may be disposed between the opening patterns SPH_3 adjacent in the first direction X.

As shown in FIG. 18 and FIG. 19, the shield pattern SP_3 according to an embodiment may include first portions SP_3a respectively disposed between the adjacent bit lines BL, and a second portion SP_3b commonly connecting the first portions SP3_a.

In an embodiment, the first portions SP_3a of the shield pattern SP_3 may be disposed between the adjacent bit lines BL. The first portions SP_3a of the shield pattern SP_3 may fill the gap regions of the spacer insulation layer 171.

The second portion SP_3b of shield pattern SP_3 may be connected to the first portions SP_3a and disposed on (e.g., disposed directly thereon) the lower surface of the bit lines BL. For example, the second portion SP_3b of the shield pattern SP_3 may be disposed on the first portions SP_3a and connects the first portions SP_3a of the shield pattern SP_3 disposed between the bit lines BL adjacent to each other.

According to an embodiment, unlike embodiments shown in FIG. 13 to FIG. 16, the opening pattern SPH_3 and the first portion SP3_a of the shield pattern SP_3 may be arranged alternately along the first direction X, with the bit line BL interposed therebetween.

Accordingly, in a cross-section, the opening pattern SPH_3 extending in the third direction Z while passing through the second portion SP_3b of the shield pattern SP_3 is disposed on one side surface of the bit line BL and the first portion SP_3a of the shield pattern SP_3 may be disposed on the other side surface of the bit line BL.

The second portion SP_3b of the shield pattern SP_3 may extend in the first direction X between the opening patterns SPH_3 disposed to be spaced apart from each other in the first direction X with at least two bit lines BL interposed therebetween and overlap at least two bit lines BL in the third direction Z (e.g., the vertical direction).

According to an embodiment, the shield insulation pattern 173 may be filled within the plurality of opening patterns SPH_3. One end of the shield insulation pattern 173 may be in direct contact with the spacer insulation layer 171, and the other end may be in direct contact with the capping insulation layer 175.

Accordingly, the shield insulation pattern 173 disposed on the one side surface of the bit lines BL is disposed to be spaced apart from the bit line BL in the first direction with the spacer insulation layer 171 interposed therebetween, and the second portion SP_3b of the shield pattern SP_3 disposed on the lower surface of the bit lines BL may be disposed to be spaced apart from the bit lines BL in the third direction Z with the spacer insulation layer 171 interposed therebetween.

Both ends of the second portion SP_3b of the shield pattern SP_3 may be disposed to be spaced apart in the first direction on the first portion SP_3a of shield pattern SP_3 with at least two bit lines BL interposed therebetween and in direct contact with each of the shield insulation patterns 173 that fill the opening pattern SPH_3.

In FIG. 18 and FIG. 19, it is shown that the shield insulation pattern 173 is filled within the plurality of opening pattern SPH_3. However, embodiments of the present disclosure are not necessarily limited thereto. For example, in some embodiments, at least a portion of each of the plurality of opening pattern SPH_3 may include an air gap.

The shield pattern SP_4 according to embodiments shown in FIG. 20 to FIG. 22 may include a plurality of opening patterns SPH_4 disposed in the cell array region CAR and the first connection regions WCR and arranged in an island pattern on a plane. The planar arrangement of the plurality of opening patterns SPH_4 according to an embodiment may be substantially equivalent to the planar arrangement of the plurality of opening pattern SPH_3 according to an embodiment shown in FIG. 17. However, the plurality of opening patterns SPH_4 according an embodiment, unlike the plurality of opening patterns SPH_3 according to embodiments shown in FIG. 17 to FIG. 19, may be further disposed not only between the adjacent bit lines BL and on the side surface of the bit lines BL, but also on the lower surface of the bit line BL.

For example, referring to FIG. 20 to FIG. 22, in the opening patterns SPH_4 according to an embodiment, compared to the opening patterns SPH_3 according to an embodiment shown in FIG. 17, the width in the first direction X may be larger. Accordingly, at least a portion of the opening patterns SPH_4 according to an embodiment may overlap with a portion of each bit line BL in the third direction Z (e.g., the vertical direction).

Accordingly, as shown in FIG. 21 and FIG. 22, each of the plurality of opening patterns SPH_4 according to an embodiment may include a first opening region SPH_4a disposed between the bit lines BL adjacent to each other and a second opening region SPH_4b connected to the first opening region SPH_4a and disposed on the first opening regions SPH_4a. The second opening region SPH_4b may extend on the first opening region SPH_4a to one side and the other side of the first direction and overlap at least a portion of the lower surfaces of the bit lines BL adjacent to each other in the third direction Z (e.g., the vertical direction).

According to an embodiment, the shield insulation pattern 173 may be filled within the plurality of opening patterns SPH_4. In an embodiment, the shield insulation pattern 173 may include a first portion 173a filling the first opening regions SPH_4a of each of the opening patterns SPH_4 and a second portion 173b filling the second opening region SPH_4b.

The shield pattern SP_4 according to an embodiment may include a first portion SP_4a respectively disposed between the adjacent bit lines BL, and a second portion SP_4b connected to the first portion SP_4a. The first portion SP_4a of the shield pattern SP_4 may fill the gap regions of the spacer insulation layer 171.

The second portion SP_4b of the shield pattern SP_4 may be connected to the first portion SP_4a of the shield pattern SP_4 and may be disposed to overlap the lower surfaces of the bit lines BL (e.g., in the third direction Z).

According to an embodiment, in a cross-section, the shield pattern SP_4 and the shield insulation pattern 173 may have substantially equivalent shapes as each other. For example, in a cross-section, the shield pattern SP_4 and the shield insulation pattern 173 may have a symmetrical shape in the first direction with the bit line BL interposed therebetween.

For example, in an embodiment the first portion SP_4a of the shield pattern SP_4 may be disposed on one side surface of the bit line BL, and the first portion 173a of the shield insulation pattern 173 may be disposed on the other side surface of the bit line BL. The first portion SP_4a of the shield pattern SP_4 and the first portion 173a of the shield insulation pattern 173 may each be disposed to be spaced apart from the bit line BL with the spacer insulation layer 171 interposed therebetween.

Additionally, the second portion SP_4b of the shield pattern SP_4 and the second portion 173b of the shield insulation pattern 173 may be disposed to overlap the lower surface of the bit line BL (e.g., in the third direction Z). For example, a portion of the lower surface of the bit line BL overlaps with the second portion SP_4b of the shield pattern SP_4 in the third direction Z (e.g., the vertical direction), and the remaining portion of the lower surface of the bit line BL may overlap with the second portion 173b of the shield insulation pattern 173 in the third direction Z (e.g., the vertical direction).

Accordingly, the second portion SP_4b of the shield pattern SP_4 and the second portion 173b of the shield insulation pattern 173 may be disposed at the substantially equivalent levels and disposed side by side along the first direction X on the lower surface of the bit lines BL.

In FIG. 21 and FIG. 22, it is shown that the shield insulation pattern 173 is filled (e.g., completely filled) within the plurality of opening patterns SPH_4. However, embodiments of the present disclosure are not necessarily limited thereto. For example, in some embodiments, at least a portion of the first portion SPH_4a of the plurality of opening patterns SPH_4 may include an air gap.

The shield pattern SP_5 according to embodiments shown in FIG. 23 to FIG. 26 may be disposed in the cell array region CAR and include a plurality of opening patterns SPH_5 arranged as an island pattern on a plane.

Even in the case of using the semiconductor device according to embodiments shown in FIG. 10 to FIG. 22, it may have a substantially equivalent effect as the semiconductor device according to an embodiment shown in FIG. 23 to FIG. 26.

However, there is a difference from embodiments as shown in FIG. 13 to FIG. 15 based on the plurality of opening pattern SPH_5 according to an embodiment is not disposed in the first connection regions WCR, and each of the plurality of opening pattern SPH_5 includes an air gap AG instead of being filled (e.g., at least partially filled) with the shield insulation pattern 173.

Referring to FIG. 23 to FIG. 26, the shield pattern SP_5 according to an embodiment may include first shield patterns SP_5a disposed between the adjacent bit lines BL and a second shield pattern SP_5b disposed on the first shield pattern SP_5a and connecting the first shield patterns SP_5a.

The first shield pattern SP_5a may be disposed between the adjacent bit lines BL and may surround the opening patterns SPH_5 on a plane. The second shield pattern SP_5b may be disposed on (e.g., disposed directly thereon) the first shield pattern SP_5a and extend in the first direction X and the second direction Y. In an embodiment, the second shield pattern SP_5b may extend in the first direction X from the cell array region CAR to the first connection regions WCR.

In an embodiment, the first shield pattern SP_5a and the second shield pattern SP_5b may include the same material as each other. However, embodiments of the present disclosure are not necessarily limited thereto, and in some embodiments, the first shield pattern SP_5a and the second shield pattern SP_5b may include different materials from each other. In FIG. 26, it is shown that there is a boundary between the first shield pattern SP_5a and the second shield pattern SP_5b. However, in an embodiment in which the first shield pattern SP_5a and the second shield pattern SP_5b include the same material as each other, the boundary between the first shield pattern SP_5a and the second shield pattern SP_5b may not be distinguishable.

The semiconductor device according to an embodiment may further include a plurality of middle insulation patterns 172 disposed between the first shield patterns SP_5a and the second shield pattern SP_5b and between the opening patterns SPH_5 and the second shield pattern SP_5b.

In an embodiment, the plurality of middle insulation patterns 172 each extends in the first direction and the second direction Y, and the plurality of middle insulation patterns 172 may be disposed to be spaced apart from each other in the second direction Y.

In an embodiment, the plurality of middle insulation pattern 172 may be disposed to overlap with a portion of the opening pattern SPH_5 and a portion of the first shield pattern SP_5a in the third direction Z between the adjacent bit lines BL, and a portion of the lower surface of the bit lines BL above the bit lines BL in the third direction Z.

One side surface of the middle insulation pattern 172 disposed on the opening pattern SPH_5 and the first shield pattern SP_5a between the adjacent bit lines BL may be in direct contact with the opening pattern SPH_5 and the spacer insulation layer 171, the other side surface may be in direct contact with the second shield pattern SP_5b, and the middle insulation pattern 172 may be covered by the second shield pattern SP_5b.

One side surface of the middle insulation pattern 172 disposed on the bit line BL may be in direct contact with the spacer insulation layer 171, the other side surface may be in direct contact with the second shield pattern SP_5b, and the middle insulation pattern 172 may be covered by the second shield pattern SP_5b.

The first shield pattern SP_5a, which does not overlap with the middle insulation pattern 172 in the third direction Z between the adjacent bit lines BL, may be in direct contact with the second shield pattern SP_5b.

Above the bit lines BL, the spacer insulation layer 171 that does not overlap with the middle insulation pattern 172 in the third direction Z may be in direct contact with the second shield pattern SP_5b.

In an embodiment, each of the plurality of opening pattern SPH_5 may include an air gap AG. For example, the plurality of first shield pattern SP_5a and the plurality of air gap AG may be alternately arranged along the second direction Y between the adjacent bit lines BL.

Accordingly, the first shield patterns SP_5a and the air gaps AG may be disposed on both sides of the bit line BL in a cross-section. Additionally, the first shield pattern SP_5a and the air gaps AG disposed between the adjacent bit lines BL may be positioned at a substantially equivalent level (e.g., an equal level) from each other.

As described above, as the side surface of the middle insulation pattern 172 is in direct contact with the opening pattern SPH_5, the air gap AG included in the opening pattern SPH_5 may be in direct contact with the middle insulation pattern 172.

In an embodiment, as the opening patterns SPH_5 disposed between the adjacent bit lines BL include the air gap AG instead of the shield insulation pattern (‘173’ in FIG. 15), a coupling capacitance by a mutual interference between the adjacent bit lines BL may be effectively reduced.

The shield pattern SP_6 according to an embodiment shown in FIG. 28 may include a plurality of opening patterns SPH_6 having different shapes and sizes from each other.

For example, the plurality of opening patterns SPH_6 according to an embodiment may include a plurality of first opening patterns SPH_6a extending the first direction X and having a line shape on a plane and a plurality of second opening patterns SPH_6b disposed between the adjacent bit lines BL and adjacent to the side surface of the bit lines BL and arranged in an island pattern on a plane. In an embodiment, the area of each of the first opening patterns SPH_6a may be greater than the area of each of the second opening patterns SPH_6b.

The first opening patterns SPH_6 may extend on one side and the other side of the first direction X from the cell array region CAR to the first connection regions WCR. Each of the first opening patterns SPH_6 may extend in the first direction X and traverse the plurality of bit lines BL.

The second opening patterns SPH_6b may be disposed to be spaced apart in the first direction X with the bit line BL interposed therebetween and may be disposed to be spaced apart in the second direction Y with the first opening pattern SPH_6a interposed therebetween. For example, the first opening patterns SPH_6a and the second opening patterns SPH_6b may be arranged alternately in the second direction Y between the adjacent bit lines BL.

The shield pattern SP_7 according to an embodiment shown in FIG. 29 may include a plurality of opening patterns SPH_7 disposed in the cell array region CAR and having different sizes from each other.

For example, the plurality of opening patterns SPH_7 according to an embodiment may include a plurality of first opening patterns SPH_7a extending in the second direction Y and disposed between the bit lines BL adjacent to each other and second opening patterns SPH_7b disposed between the adjacent bit lines BL and extending in the second direction Y.

The first opening pattern SPH_7a and the second opening patterns SPH_7b may be arranged side by side in the second direction Y between the adjacent bit lines BL.

The first opening patterns SPH_7a and the second opening patterns SPH_7b may extend in the second direction Y on a plane and have a line shape on a plane (e.g., in a plane defined in the first and second directions X, Y). The first opening pattern SPH_7a and the plurality of second opening patterns SPH_7b may have different areas from each other. For example, in an embodiment the widths in the first direction X of the first opening patterns SPH_7a and the second opening patterns SPH_7b are substantially equivalent to each other (e.g., equal to each other), and the lengths in the second direction Y of the first opening patterns SPH_7a and the second opening patterns SPH_7b are different, thereby the areas thereof may be different from each other. For example, the first opening pattern SPH_7a has a first length D1 in the second direction Y, and the second opening pattern SHP_7b has a second length D2 in the second direction Y. In an embodiment, the first length D1 may be greater than the second length D2.

The shield pattern SP_8 according to an embodiment shown in FIG. 30 may include a plurality of opening patterns SPH_8 disposed in the cell array region CAR and the first connection regions WCR.

For example, the plurality of opening patterns SPH_8 according to an embodiment may have the arrangement form substantially equivalent to the plurality of opening pattern SPH_3 according to an embodiment shown in FIG. 20. However, the plurality of opening patterns SPH_8 according to an embodiment shown in FIG. 30 may have a circular shape on a plane (e.g., in a plane defined in the first and second directions X, Y). However, embodiments of the present disclosure are not necessarily limited thereto and the planar shape of each of the plurality of opening patterns SPH_8 may vary. For example, each of the plurality of opening patterns SPH_8 may have various polygon shapes such as rhombus and hexagon.

Additionally, in some embodiments, some of the plurality of opening patterns SPH_8 may have a circular shape on a plane, and the remaining opening patterns SPH_8 may have a polygon shape other than a circle on a plane.

Even in the case of embodiments according to FIG. 28 to FIG. 30, regardless of the number, shape, size, and arrangement, etc. of the opening patterns SPH_6, SPH_7, and SPH_8 disposed between the adjacent bit lines BL, the total sum of the areas of opening patterns SPH_6, SPH_7, and SPH_8 disposed between the adjacent bit lines BL may be substantially equivalent between the adjacent bit lines BL.

Accordingly, even in the case of embodiments according to FIG. 28 to FIG. 30, it may have the substantially equivalent effect as the semiconductor device according to an embodiment.

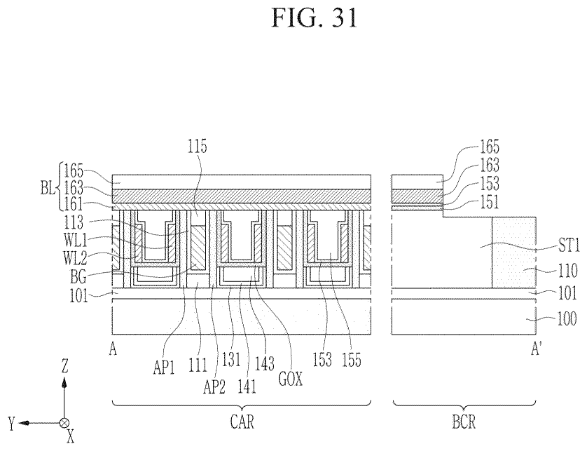

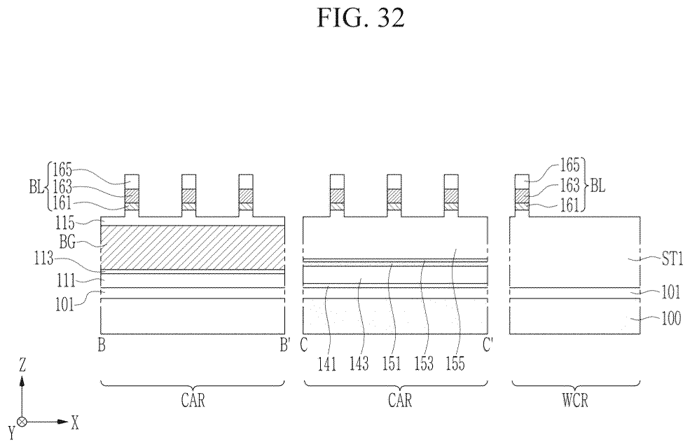

Hereinafter, the manufacturing method of the semiconductor device will be described with reference to FIG. 31 to FIG. 49. Hereinafter, the same configuration as described previously will be referred to by the same reference sign, redundant explanations will be omitted or simplified, and the differences will be mainly explained. Specifically, the method for forming the shield pattern SP including the plurality of opening pattern SPH is explained.

FIGS. 31 to 36a and FIG. 37 to FIG. 49 are cross-sectional views, perspective views, and top plan view to explain a manufacturing method of a semiconductor device according to embodiments of the present disclosure.

In detail, FIG. 31, FIG. 32, FIG. 34, FIG. 35, and FIG. 38 to FIG. 49 are cross-sectional views to explain a manufacturing method of a semiconductor device according to an embodiment. More specifically, FIG. 31, FIG. 34, FIG. 38, FIG. 40, FIG. 42, FIG. 44, FIG. 46, and FIG. 48 show a cross-section taken along the line A-A′ of FIG. 1. FIG. 32, FIG. 35, FIG. 39, FIG. 41, FIG. 43, FIG. 45, FIG. 47, and FIG. 49 represent a cross-section by cutting a line B-B′, a line C-C′, and a word line connection region in FIG. 1.

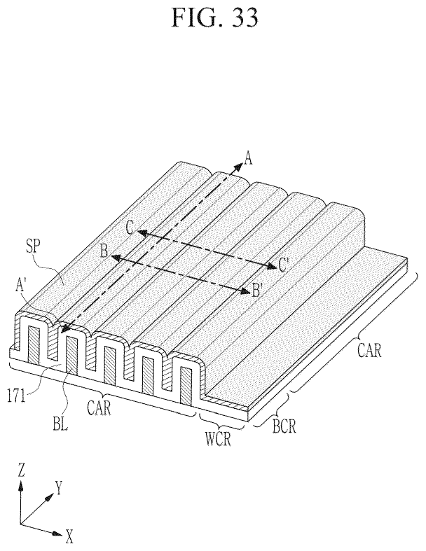

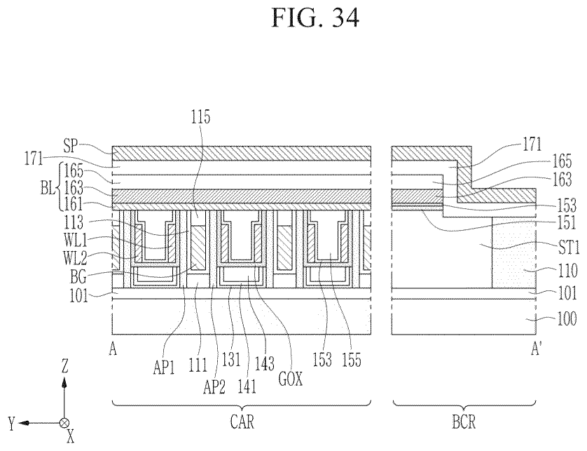

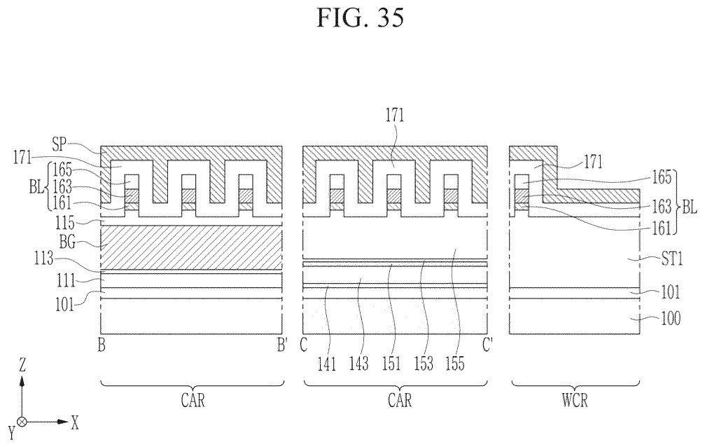

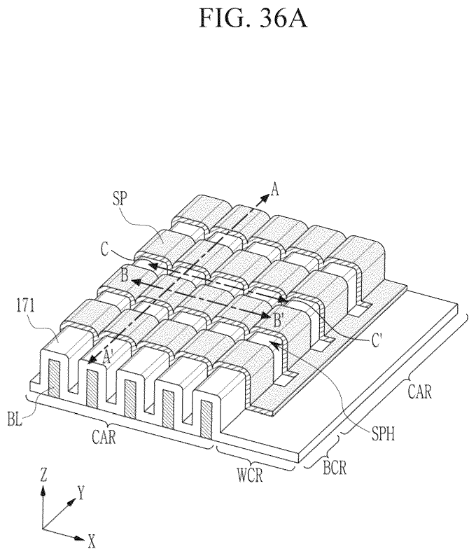

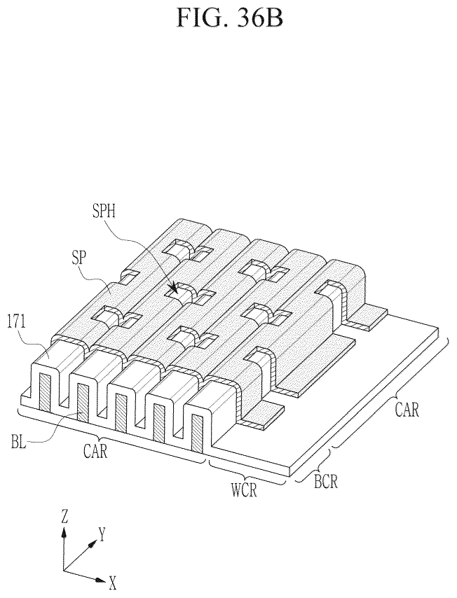

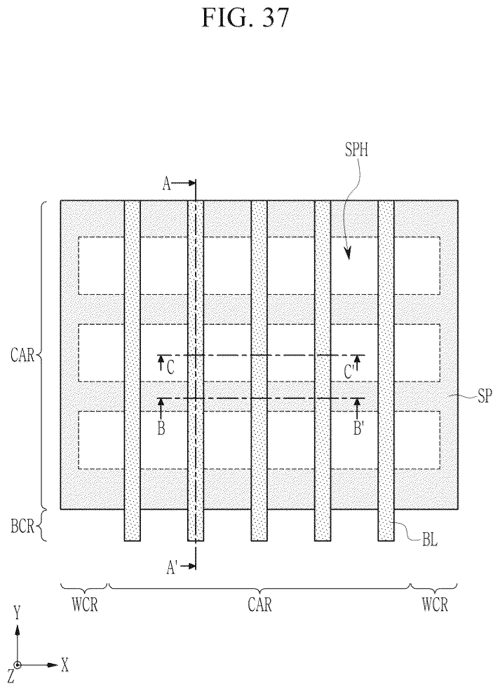

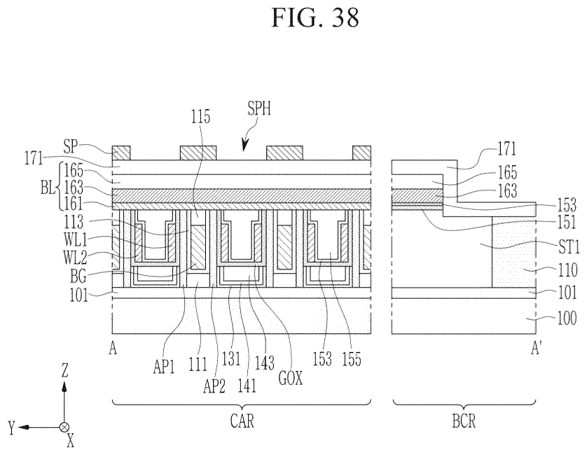

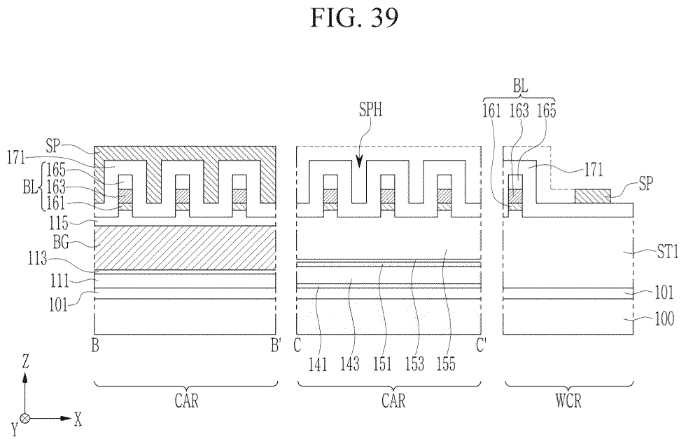

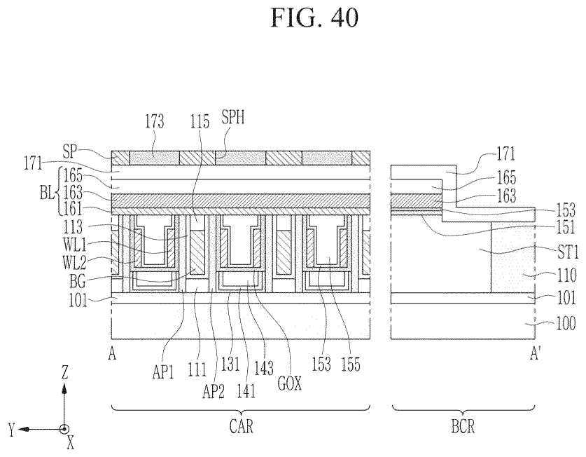

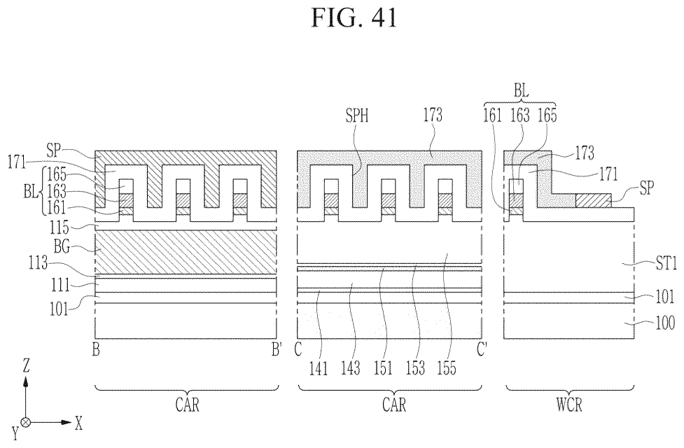

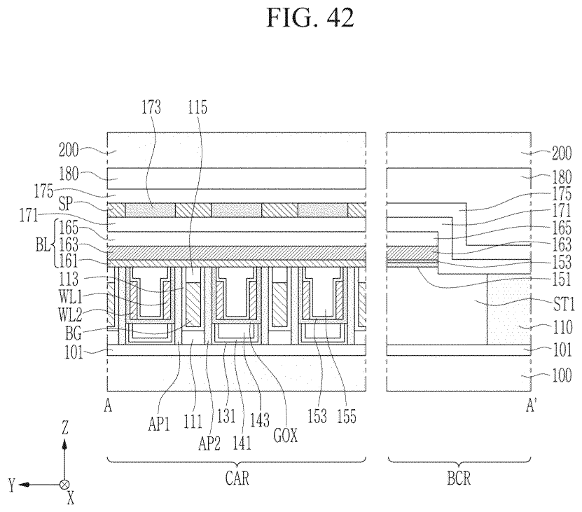

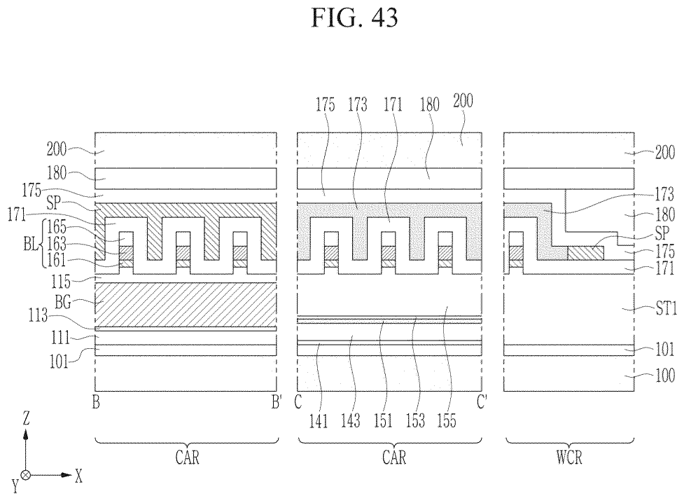

FIG. 33, FIG. 36A, and FIG. 36B are perspective views to explain a manufacturing method of a semiconductor device according to some embodiments. FIG. 37 is a top plan view to explain a manufacturing method of a semiconductor device according to an embodiment.

First, referring to FIG. 31 and FIG. 32 along with FIG. 1, a first substrate structure including a first substrate 100, a buried insulation layer 101, and an active layer may be prepared.

In an embodiment, the first substrate 100 may be, for example, a silicon substrate, a germanium substrate, and/or a silicon-germanium substrate, etc. The first substrate 100 may include word line connection regions (e.g., first connection regions; WCR) and a cell array region CAR therebetween in the first direction X parallel to the upper surface of the first substrate 100, and bit line connection regions (e.g., second connection regions; BCR) and a cell array region CAR therebetween in the second direction Y parallel to the upper surface of the first substrate 100 and intersecting the first direction X.

In an embodiment, the buried insulation layer 101 may be a buried oxide (BOX) formed by a SIMOX (separation by implanted oxygen) method or a bonding and layer transfer method. However, embodiments of the present disclosure are not necessarily limited thereto. For example, in some embodiments the buried insulation layer 101 may be an insulation layer formed by a chemical vapor deposition (CVD) method.

In an embodiment, the buried insulation layer 101 may include, for example, a silicon oxide layer, a silicon nitride layer, a silicon oxynitride layer, and/or a low dielectric layer.

The active layer may be a single crystal semiconductor film. In an embodiment, the active layer may be, for example, a single crystal silicon substrate, a germanium substrate, and/or a silicon-germanium substrate. The active layer may have a first surface and a second surface facing each other, and the second surface may be in direct contact with the buried insulation layer 101.

An isolation layer STI may be formed within the active layer of the first and second connection regions WCR and BCR. In an embodiment, the isolation layer STI may be formed by patterning the active layer of the first and second connection regions WCR and BCR to form an element separation trench that exposes the buried insulation layer 101, and then burying an insulating material within the element separation trench.

The upper surface of the isolation layer STI may be substantially formed to be coplanar with the first surface of the active layer. As the isolation layer STI is formed, a surrounding active pattern 110 may be formed in the first and second connection regions WCR and BCR.

In an embodiment, the active layer of the cell array region CAR may be etched using the mask pattern as an etching mask. For example, the active layer may be anisotropic etched. Accordingly, trenches may be formed in the active layer of the cell array region CAR.

In an embodiment, after forming gate separation patterns 111 that fill the lower part of the trenches, back gate insulation patterns 113 and back gate electrodes BG may then be formed within the trenches.

Subsequently, back gate capping patterns 115 may be formed within the trenches where the back gate electrodes BG are formed. In an embodiment, before forming the back gate capping patterns 115, impurities may be doped in the active layers through the trench where the back gate electrode BG is formed by performing a gas phase doping (GPD) process or a plasma doping (PLAD) process.

In an embodiment, a spacer film covering the side surfaces of the back gate insulation patterns 113 and the upper surfaces of the back gate capping patterns 115 may be formed with a uniform thickness. In an embodiment, depending on the deposition thickness of the spacer film, the width of the active patterns of vertical channel transistors may be determined.

In an embodiment, the spacer film may be included as an insulating material. The spacer film may include, for example, silicon oxide, silicon oxynitride, silicon nitride, silicon carbide (SiC), silicon carbon nitride layer (SiCN) and combinations thereof. However, embodiments of the present disclosure are not necessarily limited thereto.

By performing an etching process on the spacer film, a pair of spacers may be formed on the side surfaces of each back gate insulation pattern 113.

Next, the etching process for the active layer in the cell array region CAR may be performed using the spacers as an etching mask. For example, in an embodiment the active layer may be anisotropic etched. Accordingly, a pairs of preliminary active patterns separated from each other may be formed on both sides of each back gate insulation pattern 113. As the preliminary active patterns are formed, the buried insulation layer 101 may be exposed.

In an embodiment, the preliminary active patterns extend parallel to the back gate electrode BG in the first direction X and the trench may be formed between the preliminary active patterns adjacent to each other in the second direction Y.

In an embodiment, after forming the first etch stop layer 131 that conformally covers the inner surface of the trench, a first sacrificial layer may be formed to fill the trench in which the first etch stop layer 131 was formed. In an embodiment, the first etch stop layer 131 may be formed by depositing an insulating material, for example, silicon oxide. The first sacrificial layer may include an insulating material with an etching selectivity to the first etch stop layer 131. For example, in an embodiment the first sacrificial layer may be any one of insulating materials and a silicon oxide layer formed using a spin on glass (SOG) technology.

In an embodiment, after forming a mask pattern on the first sacrificial layer 133, the first sacrificial layer and first etch stop layer 131 may be sequentially etched using the mask pattern as an etching mask to form openings exposing portions of the preliminary active patterns and a portion of the upper surface of the buried insulation layer 101. During the etching process for the first sacrificial layer and the first etch stop layer 131, the spacers may be removed together.

Next, first and second active patterns AP1 and AP2 may be formed on both sides of the back gate insulation pattern 113 by anisotropic etching the preliminary active patterns. For example, the first and second active patterns AP1, AP2 may be formed on one side surface and the other side surface of the back gate electrode BG.

In an embodiment, after forming the first and second active patterns AP1 and AP2, a second sacrificial layer may be formed within the openings. The second sacrificial layer may be formed of an insulating material with an etching selectivity to the first etch stop layer 131.

In an embodiment, the first and second sacrificial layers may then be removed, and the first etch stop layer 131 may be exposed between the first and second active patterns AP1 and AP2.

In an embodiment, the second etch stop layer 141 may then be formed with a uniform thickness within the trench where the first etch stop layer 131 is formed. The second etch stop layer 141 may be formed on the first etch stop layer 131, the back gate insulation patterns 113, the back gate capping patterns 115, the portion of the buried insulation layer 101. The second etch stop layer 141 may include a material having an etching selectivity for the first etch stop layer 131.

In an embodiment, a gate capping pattern 143 may then be formed to fill (e.g., completely fill) the trench where the second etch stop layer 141 was formed. In an embodiment, the gate capping pattern 143 may be formed by forming an insulation layer by using the SOG technology and then performing an isotropic etching on the insulation layer. In an embodiment, the gate capping pattern 143 may include FSG (Fluoride silicate glass), SOG (Spin On glass), TOSZ (Tonen SilaZene). However, embodiments of the present disclosure are not necessarily limited thereto.

The level of the upper surface of the gate capping pattern 143 may vary depending on the isotropic etching process. For example, in an embodiment the upper surface of the gate capping pattern 143 may be positioned at the higher level than the lower surface of the back gate electrode BG.

In an embodiment, the first and second active patterns AP1 and AP2 may then be exposed by isotopically etching the first and second etch stop layers 131 and 141 exposed by the gate capping pattern 143. Additionally, the upper surfaces of the surrounding active pattern 110 and the isolation layer STI may be exposed in the first and second connection regions WCR and BCR.

In an embodiment, a gate insulating layer 151 that conformally covers the side surfaces of the first and second active patterns AP1 and AP2, the upper surfaces of the back gate capping patterns 115, and the upper surface of the gate capping pattern 143 may then be formed.

The gate insulating layer 151 may be formed on the surrounding active pattern 110 and the isolation layer STI in the first and second connection regions WCR and BCR.

In an embodiment, the gate insulating layer 151 be formed using at least one of technologies such as a physical vapor deposition (PVD), a thermal chemical vapor deposition (thermal CVD), a low pressure chemical vapor deposition (LP-CVD), a plasma enhanced chemical vapor deposition (PE-CVD), or an atomic layer deposition (ALD).

After depositing the gate insulating layer 151, first and second word lines WL1 and WL2 may be formed on the side surfaces of the first and second active patterns AP1 and AP2.

For example, the process of forming the first and second word lines WL1 and WL2 may include performing an etching process for the gate electrode layer after depositing a gate electrode layer conformably covering the gate insulating layer 151.

In an embodiment, during the etching process for the gate electrode layer, the gate insulating layer 151 may be used as an etch stop layer, or the gate insulating layer 151 may be over-etched to expose the gate capping pattern 143. Depending on the etching process for the gate electrode layer, the first and second word lines WL1 and WL2 may have various shapes.

The upper surfaces of the first and second word lines WL1 and WL2 may be positioned at a lower level than the upper surfaces of the first and second active patterns AP1 and AP2.

In an embodiment, after forming the first and second word lines WL1 and WL2, impurities may be doped in the first and second active patterns AP1 and AP2 through the gate insulating layer 151 exposed by the first and second word lines WL1 and WL2 by performing a gas phase doping (GPD) process or a plasma doping (PLAD) process.

In an embodiment, first gate separation pattern 153 and the second gate separation pattern 155 may then be formed sequentially within the trench where first and second word lines WL1 and WL2 are formed.

For example, the first gate separation pattern 153 can be conformally formed on the front of the first substrate 100. In an embodiment, the first gate separation pattern 153 may include, for example, silicon nitride (SiN), silicon oxynitride (SiON), silicon carbide (SiC), silicon carbon nitride layer (SiCN), or a combination thereof. The first gate separation pattern 153 may cover the surface of the word lines WL1 and WL2.

In an embodiment, the second gate separation pattern 155 may then be formed to fill the trench where the first gate separation pattern 153 was formed. In an embodiment, the second gate separation pattern 155 may be composed of an insulating material different from the material of the first gate separation pattern 153.

In an embodiment, a planarization process may then be performed on the second gate separation pattern 155, the first gate separation pattern 153, and the gate insulating layer 151 so that the upper surfaces of the back gate capping patterns 115 are exposed. Accordingly, the upper surfaces of the first and second active patterns AP1 and AP2 may be exposed, and the gate insulation pattern GOX may be formed.

In an embodiment, a polysilicon layer 161 may then be formed on the entire surface of the first substrate 100. The polysilicon layer 161 may be in direct contact with the upper surfaces of the first and second active patterns AP1 and AP2 in the cell array region CAR and may be formed on the first gate separation pattern 153 in the first and second connection regions WCR and BCR.

In an embodiment, a mask pattern exposing the first and second connection regions WCR and BCR is formed, and then the polysilicon layer 161 formed on the first and second connection regions WCR and BCR is formed using the mask pattern as an etching mask to expose the first gate separation pattern 153.

In an embodiment, a metal layer 163 and a bit line hard mask layer 165 may then be sequentially formed on the polysilicon layer 161 in the cell array region CAR. In addition, the metal layer 163 and the hard mask layer 165 may be formed sequentially on the first gate separation pattern 153 in the first and second connection regions WCR and BCR.

In an embodiment, the metal layer 163 may be formed by depositing a conductive metal nitride (e.g., titanium nitride, tantalum nitride, etc.) and a metal (e.g., tungsten, titanium, tantalum, etc.). The hard mask layer 165 may be formed by depositing an insulating material such as silicon nitride or silicon oxynitride. However, embodiments of the present disclosure are not necessarily limited thereto.

In an embodiment, a mask pattern with a line shape extending in the second direction Y may be formed on the hard mask layer 165, and the hard mask layer 165, the metal layer 163, and the polysilicon layer 161 may sequentially etched using the mask pattern. Accordingly, bit lines BL extending in the second direction Y may be formed.

In the process of forming the bit lines BL, the portions of the back gate capping pattern 115 may be etched. Also, in the process of forming the bit lines BL, the hard mask layer 165, metal layer 163, the first gate separation pattern 153, and the gate insulating layer 151 in the first and second connection regions WCR and BCR may be etched so that the portion of the isolation layer STI and the surrounding active pattern 110 may be exposed.

Next, referring to FIG. 33 to FIG. 35, after forming the bit lines BL, a spacer insulation layer 171 defining a gap region between the bit lines BL may be formed.

FIG. 33 shows that the first connection region WCR is only disposed on one side of the cell array region CAR in the first direction X. However, the first connection region WCR may also be disposed on the other side of the cell array region CAR in the first direction X, and this is omitted for better understanding and ease of description.

In an embodiment, the spacer insulation layer 171 may have the substantially uniform thickness and be formed conformally on the entire surface of the first substrate 100. The deposition thickness of the spacer insulation layer 171 may be less than half of the gap between the adjacent bit lines BL. In this way, by depositing the spacer insulation layer 171, the gap regions may be defined between the bit lines BL. The gap region may extend parallel to the bit lines BL in the second direction Y.

In an embodiment, a shield pattern SP may be formed on the spacer insulation layer 171. The shield pattern SP may be formed conformally on the entire surface of the first substrate 100. Accordingly, the shield pattern SP may be formed in the cell array region CAR and the first and second connection regions BCR and WCR.

In an embodiment, the shield pattern SP may fill (e.g., completely fill) the gap regions of the spacer insulation layer 171 and be conformally formed on the spacer insulation layer 171.

In an embodiment in which the shield pattern SP is deposited on the spacer insulation layer 171 by using a chemical vapor deposition (CVD) method, discontinuous boundary surfaces, for example, seams, may be formed within the gap regions due to step coverage properties.

In an embodiment, the shield pattern SP may include, for example, a metallic material such as tungsten (W), titanium (Ti), nickel (Ni), or cobalt (Co). As another example, the shield pattern SP may include a conductive two-dimensional (2D) material such as graphene. However, embodiments of the present disclosure are not necessarily limited thereto.

Next, referring to FIG. 36A to FIG. 39, the shield pattern SP may be patterned to form a plurality of opening patterns SPH.

In FIG. 36A and FIG. 36B, the first connection region WCR is shown as being disposed only on one side of the cell array region CAR in the first direction X. However, in some embodiments the first connection region WCR may be also disposed on the other side of the cell array region CAR in the first direction X and this is omitted for better understanding and ease of description.

In an embodiment, after forming a mask layer on the shield pattern SP of the cell array region CAR and the first connection region WCR, a mask pattern may be formed by using a photo and etching process.

The mask pattern extends across the plurality of bit lines BL in the first direction X from the cell array region CAR to the first regions WCR. The mask pattern includes a plurality of openings having a line shape on a plane, and the plurality of openings may be disposed to be spaced apart in the second direction Y.

The mask pattern may expose the shield pattern SP through the opening in the cell array region CAR. Additionally, the mask pattern may expose the portion of the shield pattern SP in the first connection regions WCR, and the mask pattern may expose the shield pattern SP in the second connection regions BCR.

Next, the shield pattern SP may be etched by using the mask pattern as an etching mask. Accordingly, the shield pattern SP exposed by the opening of the mask pattern in the cell array region CAR may be patterned, thereby forming a plurality of opening pattern SPHs exposing the spacer insulation layer 171.

For example, the shield pattern SP disposed between the bit lines BL in the cell array region CAR and the shield pattern SP disposed on the upper surface and the side surface of the bit lines BL may be etched. For example, in the cell array region CAR, as the shield pattern SP is etched to be removed, the gap region of the spacer insulation layer 171 disposed between the bit lines BL and the spacer insulation layer 171 disposed on the upper surface and the side surface of the bit line BL may be exposed.

In an embodiment, each of the plurality of opening patterns SPH may extend in the first direction X from the cell array region CAR to the first connection regions WCR, and the plurality of opening pattern SPHs may be disposed to be spaced apart from each other in the second direction Y.

The portion of the shield pattern SP exposed by the mask pattern is removed in the first connection region WCR so that the upper surface of the spacer insulation layer 171 is exposed, and the end portion of the shield pattern SP may be disposed on the upper surface of the spacer insulation layer 171 in the first connection region WCR. Also, the shield pattern SP exposed by the mask pattern in the second connection region BCR is removed so that the upper surface of the spacer insulation layer 171 and the gap region of the spacer insulation layer 171 disposed between the bit line BL may be exposed.

However, embodiments of the present disclosure are not necessarily limited thereto. For example, in some embodiments as shown in FIG. 36B, by patterning the shield pattern SP, a plurality of opening patterns SPH arranged in an island pattern on a plane may be formed.

For example, by patterning the mask layer, the mask pattern including the plurality of openings arranged in a zigzag orientation along the second direction Y with the bit line BL interposed therebetween in the cell array region CAR and arranged in an island pattern on a plane may be formed.

By the plurality of openings included in the mask pattern, the shield pattern SP disposed between the bit lines BL adjacent to each other and at least a portion of the shield pattern SP disposed on the upper surface of the bit line BL may be exposed.

Also, by the opening included in the mask pattern, in the first connection regions WCR, the shield pattern SP disposed on the upper surface and the side surface of the bit line BL and a portion of the shield pattern SP disposed adjacent to the bit line BL may be exposed.

Accordingly, by using the mask pattern including the plurality of openings as an etching mask, as shown in FIG. 36B, a plurality of opening patterns SPH arranged in a zigzag orientation along the second direction Y with the bit line BL interposed therebetween in the cell array region CAR and arranged in an island pattern on a plane may be formed.

The plurality of opening patterns SPH may expose the gap region of the spacer insulation layer 171 disposed between the bit lines BL in the cell array region CAR and a portion of the spacer insulation layer 171 disposed on the upper surface and the side surface of the bit lines BL.

Also, in the first connection regions WCR, the plurality of opening patterns SPH may expose the upper surface of the spacer insulation layer 171.

In an embodiment, referring to FIG. 40 and FIG. 41, a shield insulation pattern 173 may then be filled within the plurality of opening patterns SPH formed in the shield pattern SP. In an embodiment, the process of forming the shield insulation pattern 173 may include a process of planarizing the upper surface of the shield pattern SP and the upper surface of the shield insulation pattern 173 to be positioned on a substantially equivalent level (e.g., a substantially equal level) after forming the shield insulation pattern 173 to fill each of the plurality of opening patterns SPH. Accordingly, the upper surface of the shield pattern SP and the upper surface of the shield insulation pattern 173 may have a substantially flat upper surface.

The shield insulation pattern 173 may include an insulating material. For example, in an embodiment the shield insulation pattern 173 may include at least one of silicon oxide, silicon nitride, silicon oxynitride, a low dielectric constant (low-k) material such as SiOCN, SiOC, SiBN, SiBCN, SiBCON or combination thereof. However, the material included in the shield insulation pattern 173 is not necessarily limited thereto and may be changed in various ways.

In an embodiment, referring to FIG. 42 and FIG. 43, a capping insulation layer 175 may then be formed on the shield pattern SP and the shield insulation pattern 173. The capping insulation layer 175 may conformally cover the shield pattern SP and the shield insulation pattern 173, and fill the gap regions of the spacer insulation layer 171 in the second connection region BCR. In an embodiment, the capping insulation layer 175 may include, for example, silicon nitride.

In an embodiment, a planarized insulation layer 180 may then be formed on the capping insulation layer 175. In an embodiment, the planarized insulation layer 180 may include an insulating material having an etching selectivity for the capping insulation layer 175. For example, the planarized insulation layer 180 may include insulating materials formed by using a spin on glass (SOG:) technique and a silicon oxide layer. The planarized insulation layer 180 may have a substantially flat upper surface.

In an embodiment, a second substrate 200 may be bonded on the planarized insulation layer 180. The second substrate 200 may be bonded to the upper surface of the planarized insulation layer 180 by using an adhesive film. In an embodiment, the second substrate 200 may include, for example, a single crystal silicon or glass (e.g., quartz). However, embodiments of the present disclosure are not necessarily limited thereto.

In an embodiment, referring to FIG. 44 and FIG. 45, after bonding the second substrate 200, a lapping process of removing the first substrate 100 may then be performed. In an embodiment, the process of removing the first substrate 100 may include sequentially performing a grinding process and a dry etching process to expose the buried insulation layer 101.

In an embodiment, referring to FIG. 46 and FIG. 47, the buried insulation layer 101 may be removed to expose the active patterns AP1 and AP2, the gate separation patterns 111, and the back gate insulation patterns 113. Also, in the first and second connection regions WCR and BCR, the second surface of the surrounding active pattern 110 may be exposed.

In an embodiment, the buried insulation layer 101 may be etched by performing a wet or dry etching process. During the etching process for the buried insulation layer 101, the active patterns AP1 and AP2 may be used as an etch stop layer.

In an embodiment, in the cell array region CAR, third and fourth etch stop layers 211, and 213 may then be sequentially formed. In an embodiment, the third etch stop layer 211 may include silicon oxide and may be deposited on the active patterns AP1 and AP2, the gate separation patterns 111, and the isolation layer STI. The fourth etch stop layer 213 may be formed of a material having an etching selectivity for the third etch stop layer 211 and may include, for example, silicon nitride.

In an embodiment, in the first and second connection regions WCR and BCR, a surrounding transistor may then be formed on the second surface of the surrounding active pattern 110.

For example, in the first and second connection regions WCR and BCR, a surrounding gate insulating layer 215 covering the second surface of the surrounding active pattern 110 may be formed and a surrounding gate electrode PG may be formed on the surrounding gate insulating layer 215.

In an embodiment, the surrounding gate electrode PG may include a surrounding conductive pattern 221, a surrounding metal pattern 223, and a surrounding mask pattern 225 deposited sequentially.

In an embodiment, an interlayer insulating layer 231 and a fifth etch stop layer 233 may be formed in the cell array region CAR and the first and second connection regions WCR and BCR. For example, the interlayer insulating layer 231 may be formed by depositing an insulating material and then planarizing it to expose the upper surface of the surrounding gate electrode PG. The fifth etch stop layer 233 may include an insulating material having an etching selectivity for the interlayer insulating layer 231. The fifth etch stop layer 233 may cover the upper surface of the interlayer insulating layer 231 and the upper surface of the surrounding gate electrode PG.

In an embodiment, contact patterns BC connected to the first and second active patterns AP1 and AP2 through the interlayer insulating layer 231 and the fifth etch stop layer 233 may then be formed.

In an embodiment, the process of forming the contact patterns BC may include patterning the interlayer insulating layer 231 and the fifth etch stop layer 233 to form holes respectively exposing the first and second active patterns AP1 and AP2, depositing a conductive layer filling the holes, and planarizing the conductive layer to expose the upper surface of the fifth etch stop layer 233.

After forming the contact patterns BC, in the first and second connection regions WCR and BCR, surrounding contact plugs PCPa, PCPb, and PCPc may be formed.

In an embodiment, the process of forming the surrounding contact plugs PCPa, PCPb, and PCPc may include patterning the fifth etch stop layer 233, the interlayer insulating layer 231, and the isolation layer STI to form contact holes, and depositing a conducting material to fill the contact holes on the fifth etch stop layer 233.

In an embodiment, the surrounding contact plugs PCPa, PCPb, and PCPc may include a bit line contact plug PCPa connected to the end portion of the bit line BL through the fifth etch stop layer 233, the interlayer insulating layer 231, and the isolation layer STI, such as the end portion of the metal layer 163, a shield contact plug PCPb connected to the end portion of the shield pattern SP, and a surrounding contact plug PCPc connected to the source/drain region of the surrounding transistor.

In an embodiment, referring to FIG. 48 and FIG. 49, in the cell array region CAR, a patterning may then be performing to form landing pads LP connected to the contact patterns BC, respectively.

The process of forming the landing pads LP may include etching the fifth etch stop layer 233 and the interlayer insulating layer 231 between the landing pads LP and the contact patterns BC by using the mask patterns to form recess region and burying an insulating material within the recess region for form a pad separation insulation pattern 245.

In an embodiment, a portion of the contact patterns BC may be etched while forming the recess region. In an embodiment, the upper surface of the pad separation insulation pattern 245 may be substantially coplanar with the upper surfaces of the landing pads LP (e.g., in the third direction Z).

In an embodiment, the landing pads LP and the surrounding contact plugs PCPa, PCPb, and PCPc may be formed simultaneously. The pad separation insulation pattern 245 may insulate the peripheral circuit wires 241a, 241b, and 241c in the first and second connection regions WCR and BCR from each other.

In an embodiment, a sixth etch stop layer 247 covering the upper surfaces of the landing pads LP and the upper surfaces of the peripheral circuit wires 241a, 241b, and 241c may then be formed. The sixth etch stop layer 247 may cover the upper surface of the pad separation insulation pattern 245 and the upper surfaces of the peripheral circuit wires 241a, 241b, and 241c. The sixth etch stop layer 247 may include an insulating material having an etching selectivity for the pad separation insulation pattern 245.

In an embodiment, storage electrodes 251 respectively connected to the landing pads LP may be formed by penetrating the sixth etch stop layer 247. In an embodiment, the storage electrodes 251, for example, may include a doped polysilicon, a conductive metal nitride (e.g., titanium nitride, tantalum nitride, the like), and a metal (e.g., tungsten, titanium, tantalum, the like), a conductive metal silicide, a conductive metal oxide, or a combination thereof.

As shown in FIG. 4 and FIG. 5, a capacitor dielectric layer 253 conformally covering the surface of the storage electrodes 251 may then be formed. In an embodiment, a plate electrode 255 may then be formed on the dielectric layer 253.

After forming the data storage patterns DSP, a peripheral circuit insulation layer 263 covering the first and second connection regions WCR and BCR may be formed, and an upper insulation layer 270 may be formed on the data storage patterns DSP and the peripheral circuit insulation layer 263.

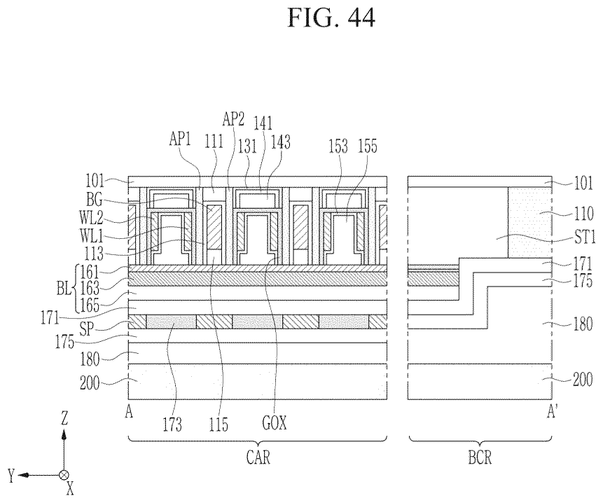

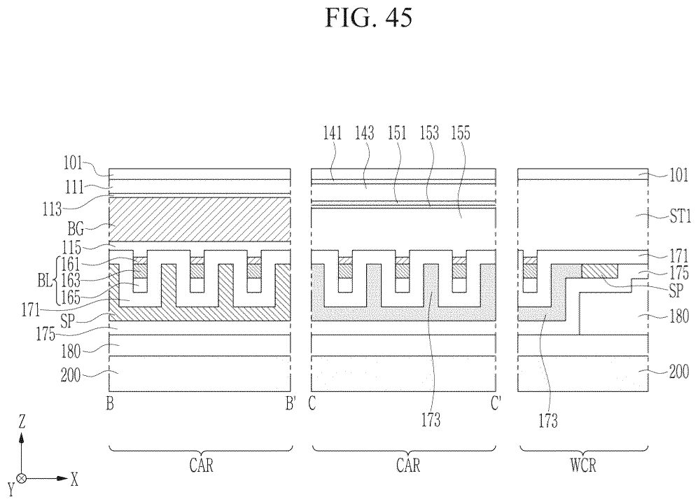

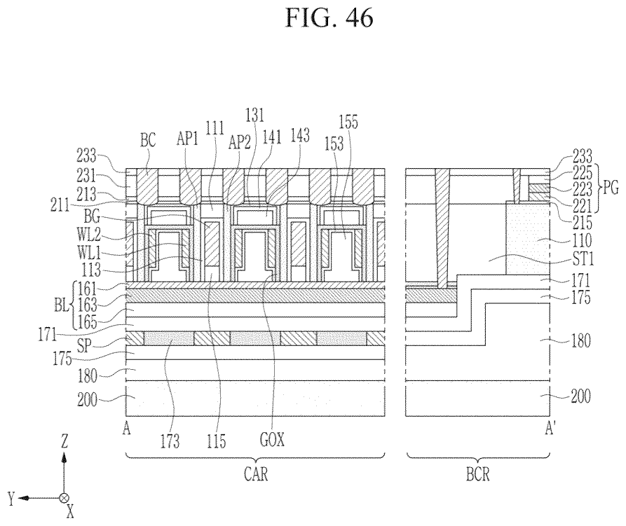

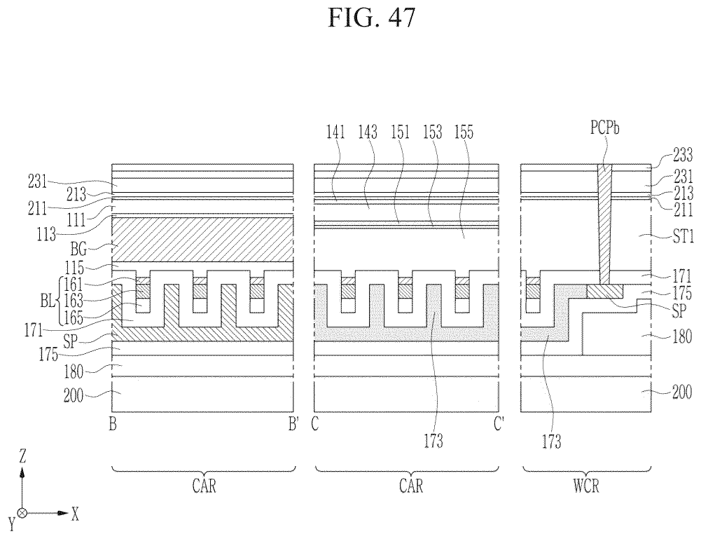

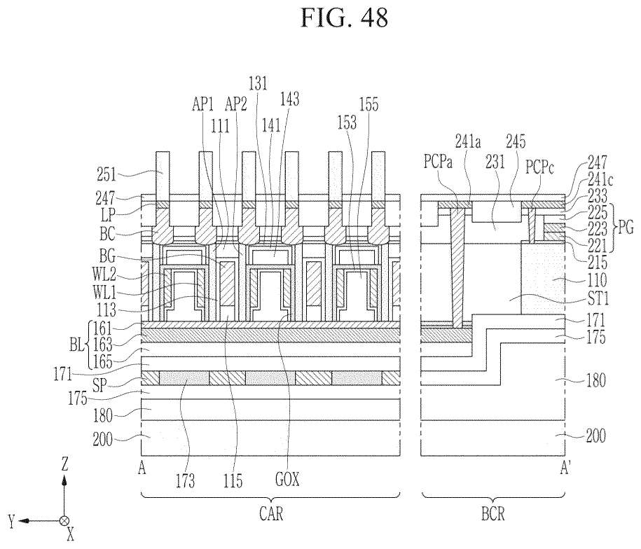

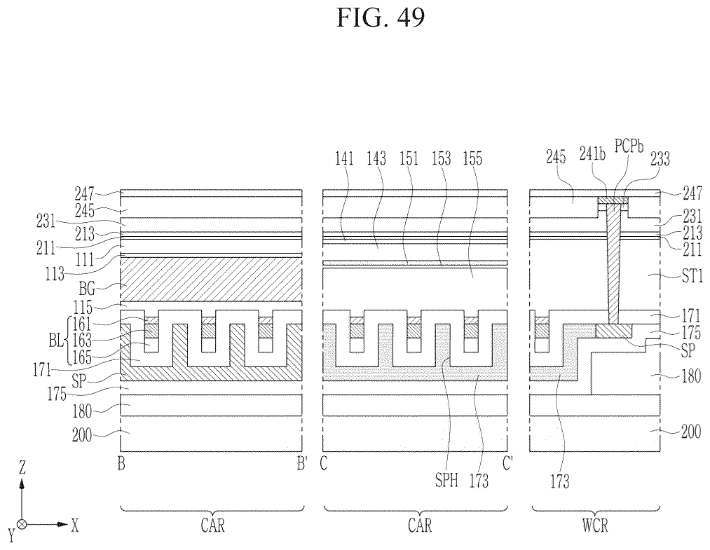

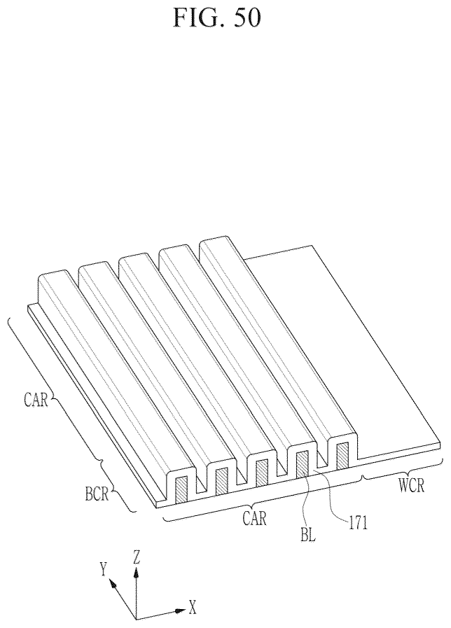

Hereinafter, a manufacturing method of the semiconductor device according to an embodiment is described with reference to FIG. 50 to FIG. 55. In the following embodiment, the same configuration as the previously described embodiment will be referred to by the same reference numeral, redundant description will be omitted or simplified, and the differences will be mainly explained for economy of description.

Specifically, the method for forming a shield pattern SP including a plurality of opening pattern SPH is mainly explained.

FIG. 50 to FIG. 55 are perspective views to explain a manufacturing method of a semiconductor device according to embodiments.

FIG. 50 to FIG. 55 shows that the first connection region WCR is disposed only on one side of the cell array region CAR in the first direction X, but the first connection regions WCR may be also disposed on the other side of the cell array region CAR in the first direction X, and a view therefor is omitted for better understanding and ease of description.

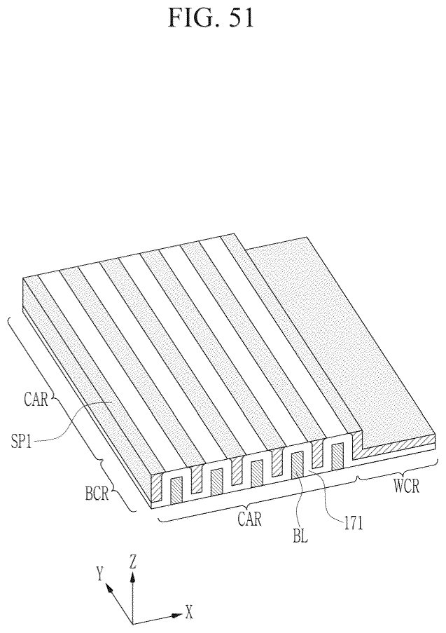

Referring to FIG. 50 and FIG. 51, after forming the bit lines BL, a spacer insulation layer 171 defining a gap region between the bit lines BL may be formed.

In an embodiment, the first shield pattern SP1 may be conformally formed on the spacer insulation layer 171. Accordingly, the first shield pattern SP1 may be formed in the cell array region CAR and the first and second connection regions BCR and WCR. The first shield pattern SP1 may fill the gap region of the spacer insulation layer 171 and conformally cover the upper surface and the side surface of the spacer insulation layer 171. Additionally, in the first connection regions WCR, the first shield pattern SP1 may conformally cover the upper surface of the spacer insulation layer 171.

In an embodiment, in the cell array region CAR, a planarization process may then be performed so that the upper surface of the first shield pattern SP1 disposed between the adjacent bit lines BL and the side surface of the bit lines BL and filling the gap region of the spacer insulation layer 171 and the upper surface of the spacer insulation layer 171 covering the upper surface of the bit line BL may be positioned on a substantially equivalent level as each other (e.g., a substantially equal level). For example, the first shield pattern SP1 disposed on the upper surface of the spacer insulation layer 171 may be removed in the cell array region CAR through the planarization process.

Accordingly, the gap region of the spacer insulation layer 171 between the adjacent bit lines BL and the first shield patterns SP1 disposed on the side surface of the spacer insulation layer 171 and extending in the second direction Y may be formed. Additionally, the upper surfaces of the first shield pattern SPs may be substantially flat as the upper surfaces of the spacer insulation layer 171 covering the upper surface of the bit line BL.

In an embodiment, referring to FIG. 53, in the cell array region CAR, a portion of the first shield pattern SP1 may then be patterned to form a plurality of opening patterns SPH.

By patterning the first shield pattern SP1s, the plurality of opening pattern SPHs arranged in an island pattern on a plane may be formed. For example, in an embodiment after forming a mask layer, by patterning the mask layer, a mask pattern including a plurality of openings arranged in an island pattern on a plane in the cell array region CAR may be formed

Some of the first shield pattern SP1s may be exposed to the plurality of openings included in the mask pattern.

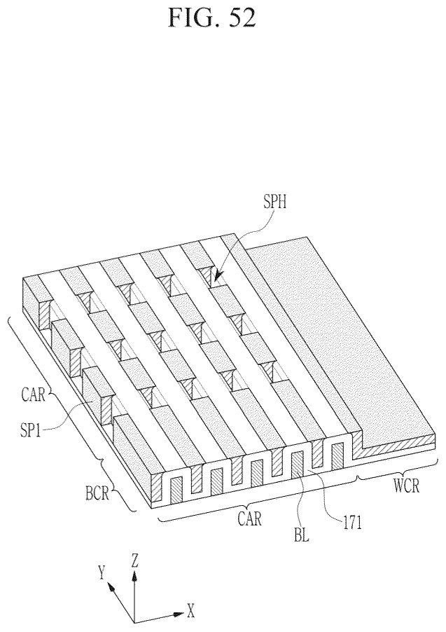

In an embodiment, by using the mask pattern including the plurality of openings as an etching mask, as shown in FIG. 52, in the cell array region CAR, a plurality of opening patterns SPH arranged to be spaced apart in the second direction Y between the bit lines BL and arranged in an island pattern on a plane may be formed.

In an embodiment, as shown in FIG. 53, a plurality of opening patterns SPH may be filled with a sacrificial pattern 137. In an embodiment, the process of forming the sacrificial pattern 137 may include a process of planarizing the spacer insulation layer 171 after forming the sacrificial pattern 137 within the plurality of opening patterns SPH so that the upper surface of the sacrificial pattern 137, the upper surface of the first shield pattern SP1, and the upper surface of the spacer insulation layer 171 may be substantially flat.

In an embodiment, the sacrificial pattern 137 may include materials such as a spin on coating (SOH), a photoresist. However, the material of sacrificial pattern 137 is not necessarily limited thereto and may be changed in various ways.

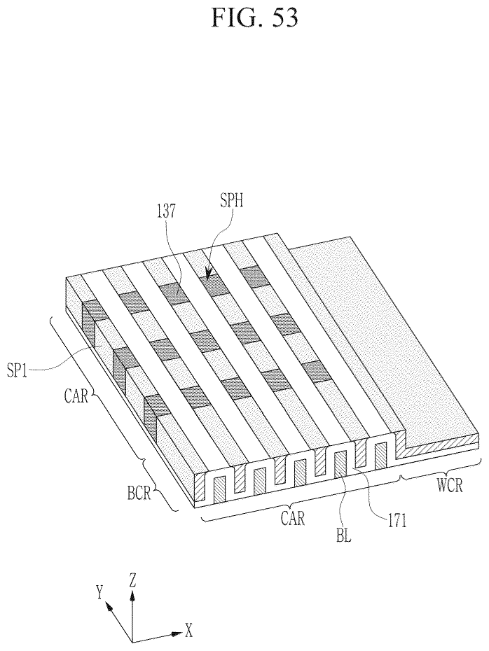

In an embodiment, further referring to FIG. 54 along with FIG. 53, after forming a plurality of middle insulation patterns 172 on the plurality of opening patterns SPH, the sacrificial pattern 137 may be removed to form an air gap AG within the plurality of opening pattern SPH.

In an embodiment, the plurality of middle insulation pattern 172 may be formed by forming an insulating material layer and then patterning the insulating material layer. For example, the insulating material layer to form the middle insulation pattern 172 may include silicon oxide. However, embodiments of the present disclosure are not necessarily limited thereto. The middle insulation pattern 172 may be formed through an atomic layer deposition (ALD) method. However, the method of forming the middle insulation pattern 172 is not necessarily limited thereto and may be changed in various ways.

In an embodiment, the plurality of middle insulation pattern 172 may extend in the cell array region CAR in the first direction X and be formed to be spaced apart from each other in the second direction Y. The plurality of middle insulation pattern 172 may be formed to overlap each portion of the plurality of opening patterns SPH in the third direction Z. For example, each end of the plurality of middle insulation pattern 172 may be formed to expose a portion of the sacrificial pattern 137 filled in the plurality of opening pattern SPH. For example, the end of the middle insulation pattern 172 and the end of the opening pattern SPH may be spaced apart in the second direction Y to expose the sacrificial pattern 137 positioned between them.

In an embodiment, the air gap AG may then be formed by removing the sacrificial pattern 137 filled in each of the plurality of opening patterns SPH. The sacrificial pattern 137 may be removed through the space between the end of the middle insulation pattern 172 and the end of the opening pattern SPH. For example, in an embodiment the sacrificial pattern 137 may be removed by an evaporation process. However, the method for removing the sacrificial pattern 137 is not necessarily limited thereto and may be changed in various ways.

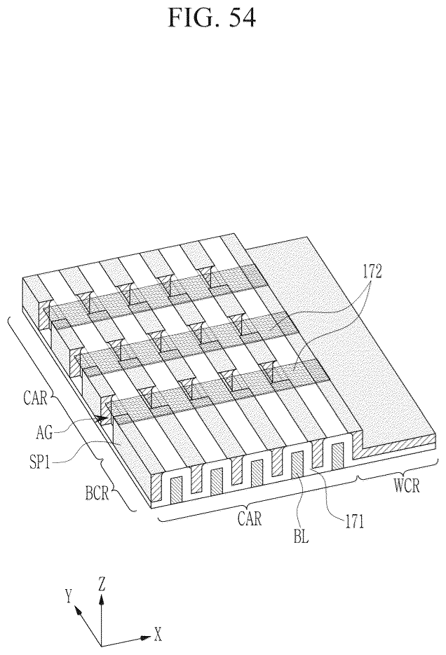

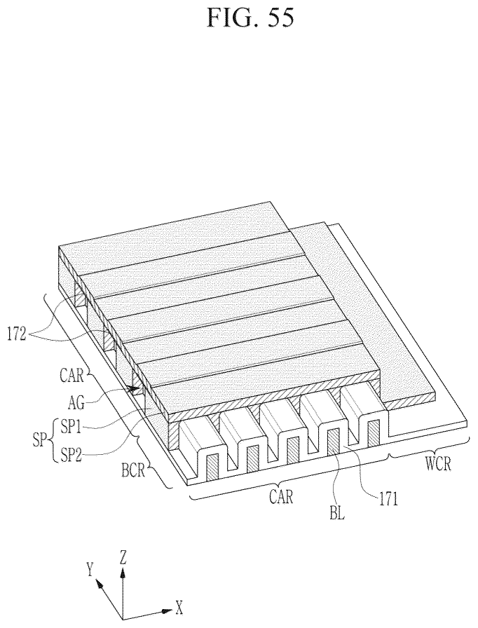

In an embodiment, referring to FIG. 55, a second shield pattern SP2 may then be formed on the first shield pattern SP1. The second shield pattern SP2 may be formed conformally to have a substantially uniform thickness. Accordingly, the first shield pattern SP1 and the second shield pattern SP2 may form a shield pattern SP.

The second shield pattern SP2 may be formed on the first shield pattern SP1, the spacer insulation layer 171, and the middle insulation pattern 172 in the cell array region CAR, and formed on the first shield pattern SP1 and the spacer insulation layer 171 in the first and second connection regions BCR and WCR.

As the second shield pattern SP2 is formed on the middle insulation pattern 172, the middle insulation pattern 172 may be disposed between the first shield pattern SP1 and the second shield pattern SP2. For example, the lower surface of the middle insulation pattern 172 may be in direct contact with the first shield pattern SP1, and the middle insulation pattern 172 may be covered by the second shield pattern SP2.

In an embodiment, the first shield pattern SP1 and the second shield pattern SP2 may include the same material. In an embodiment in which the first shield pattern SP1 and the second shield pattern SP2 include the same material, the boundary between the first shield pattern SP1 and the second shield pattern SP2 may not be distinguishable. However, embodiments of the present disclosure are not necessarily limited thereto, and the first shield pattern SP1 and the second shield pattern SP2 may include different materials from each other.

In an embodiment, after forming a mask pattern on the shield pattern SP, the shield pattern SP may be patterned. For example, the shield pattern SP may be etched using the mask pattern as an etching mask.

In an embodiment, a portion of the shield pattern SP exposed by the mask pattern in the first connection region WCR is then removed so that the upper surface of the spacer insulation layer 171 is exposed, and the end portion of the shield pattern SP may be disposed on the upper surface of the spacer insulation layer 171 in the first connection region WCR. Also, in the second connection region BCR, the shield pattern SP exposed by the mask pattern may be removed so that the upper surface of the spacer insulation layer 171 and the gap region of the spacer insulation layer 171 disposed between the bit lines BL may be exposed.

The subsequent processes are substantially equivalent to the above-mentioned processes with reference to FIG. 42 to FIG. 49, so the description thereof is omitted for economy of description.

While the present disclosure has been described in connection with non-limiting embodiments, it is to be understood that the present disclosure is not limited to the described embodiments. On the contrary, the present disclosure covers all modifications and equivalent arrangements included within the spirit and scope of the present disclosure.

What is claimed is:

1. A semiconductor device comprising:
a substrate;
bit lines disposed on the substrate and extending in a first direction;
a shield pattern disposed on the bit lines;
a first word line disposed on the bit lines, the first word line extending in a second direction crossing the first direction;
a second word line extending on the bit lines in the second direction and spaced apart from the first word line in the first direction; and
a first active pattern and a second active pattern disposed on the bit lines and positioned between the first word line and the second word line,
wherein the shield pattern includes an opening pattern disposed between adjacent bit lines of the bit lines.

2. The semiconductor device of claim 1, wherein:
the shield pattern includes:
first portions disposed between the adjacent bit lines; and
a second portion connected to the first portions and disposed on a lower surface of the bit lines, and
the first portions and the second portion are integrally formed.

3. The semiconductor device of claim 2, wherein:
at least a portion of the opening pattern overlaps the lower surface of the bit lines in a vertical direction.

4. The semiconductor device of claim 3, wherein:
the opening pattern includes a first opening region disposed between the bit lines; and
a second opening region connected to the first opening region and disposed on at least a portion of the lower surface of the bit lines.

5. The semiconductor device of claim 1, wherein:
the opening pattern extends along the second direction and has a line shape on a plane; and
the opening pattern overlaps the bit lines in a vertical direction.

6. The semiconductor device of claim 5, wherein:
the opening pattern includes a first opening pattern extending in the second direction and having a line shape on a plane; and
a second opening pattern spaced apart from the first opening pattern in the first direction, the second opening pattern extending in the second direction, and having a line shape on a plane; and
a width along the first direction of the first opening pattern is different from a width along the first direction of the second opening pattern.

7. The semiconductor device of claim 1, wherein:
the opening pattern includes a plurality of opening patterns arranged in an island pattern on a plane.

8. The semiconductor device of claim 7, wherein:
the plurality of opening patterns is arranged in a zigzag orientation along the first direction with the bit lines interposed therebetween.

9. The semiconductor device of claim 7, wherein:
at least a portion of the plurality of opening patterns overlaps with at least a portion of a lower surface of the bit lines in a vertical direction.

10. The semiconductor device of claim 1, further comprising:
a shield insulation pattern filling the opening pattern; and
the shield insulation pattern includes at least one compound selected from SiO, SiOC, SiON, SiOCN, SiN and combinations thereof.

11. The semiconductor device of claim 1, further comprising:
an air gap disposed in the opening pattern between the adjacent bit lines.

12. The semiconductor device of claim 11, wherein:
the shield pattern further includes first shield patterns disposed between the adjacent bit lines;
a second shield pattern disposed on the first shield patterns and commonly connecting the first shield pattern; and
a middle insulation pattern disposed between the first shield patterns and the second shield pattern and between the second shield pattern and the air gap.

13. A semiconductor device comprising:
a substrate including a cell array region and a connection region;
bit lines disposed on the substrate and extending in a first direction;
a shield pattern disposed on the bit lines;
a first word line disposed on the bit lines, the first word line extending in a second direction crossing the first direction;
a second word line extending on the bit lines in the second direction and spaced apart from the first word line in the first direction,
a first active pattern and a second active pattern disposed on the bit lines and positioned between the first word line and the second word line; and
a back gate electrode respectively disposed between the first and second active patterns adjacent to each other, the back gate electrode extending across the bit lines in the second direction,
wherein the shield pattern includes:
first portions disposed between the bit lines;
a second portion connected to the first portions and disposed on a lower surface of the bit lines; and
a plurality of opening patterns disposed between adjacent bit lines of the bit lines;
each of the plurality of opening patterns disposed between the bit lines has a substantially same total sum of an area.

14. The semiconductor device of claim 13, wherein:
each of the plurality of opening patterns includes a first opening region disposed between the bit lines; and
a second opening region connected to the first opening region and disposed on the first portions,
wherein a shield insulation pattern fills the first opening region and the second opening region.

15. The semiconductor device of claim 14, wherein:
areas of at least some of the plurality of opening patterns are different from each other.

16. The semiconductor device of claim 14, further comprising:
a spacer insulation layer disposed on the bit lines and conformally covering the bit lines; and
the spacer insulation layer is disposed between the shield insulation pattern and the bit lines, and between the bit lines and the shield pattern.

17. The semiconductor device of claim 14, wherein:
an air gap is disposed in the first opening region.

18. The semiconductor device of claim 13, wherein:
the connection region includes:
a first connection region disposed adjacent to the cell array region in the first direction; and
a second connection region disposed adjacent to the cell array region in the second direction;
wherein the semiconductor device further comprises a bit line contact plug connected to the bit lines in the first connection region; and
a shield contact plug connected to the second portion of the shield pattern in the second connection region.

19. A semiconductor device comprising:
a substrate including a cell array region and a connection region;
a peripheral circuit structure disposed on the substrate, the peripheral circuit structure including peripheral circuits and a peripheral circuit insulation layer covering the peripheral circuits;
bit lines disposed on the peripheral circuit structure and extending in a first direction;
a shield pattern disposed between the substrate and the bit lines and including a plurality of opening patterns,
a first word line disposed on the bit lines, the first word line extending in a second direction crossing the first direction;
a second word line disposed on the bit lines, the second word line extending in the second direction and spaced apart from the first word line in the first direction;
a first active pattern and a second active pattern disposed on the bit lines and positioned between the first word line and the second word line;
a back gate electrode disposed respectively between the first and second active patterns, the back gate electrode extending across the bit lines in the second direction; and
a shield insulation pattern filling the plurality of opening patterns,
wherein the shield pattern includes:
first portions disposed between the bit lines, and
a second portion connected to the first portions and disposed on a lower surface of the bit lines; and
each of the plurality of opening patterns disposed between adjacent bit lines of the bit lines has a substantially same total sum of an area.

20. The semiconductor device of claim 19, wherein:
the connection region includes:
a first connection region disposed adjacent to the cell array region in the first direction; and
a second connection region adjacent to the cell array region in the second direction, and
wherein the semiconductor device further comprises a surrounding active pattern disposed in the first and second connection region;
an isolation layer surrounding the surrounding active pattern;
a bit line contact plug penetrating the isolation layer in the first connection region and connected to the bit lines; and
a shield contact plug penetrating the isolation layer in the second connection region and connected to the second portion of the shield pattern.
